(19) United States
(12) Patent Application Publication
(10) Pub. No.: US 2010/0213605 A1
(43) Pub. Date: Aug. 26, 2010

(54) SEMICONDUCTOR DEVICE AND METHOD OF MANUFACTURING SEMICONDUCTOR DEVICE

(75) Inventor: Noriyoshi Shimizu, Nagano-shi (JP)

Correspondence Address: IPUSA, P.L.L.C, 1054 31ST STREET, N.W., Suite 400, Washington, DC, 20007, US

(73) Assignee: SHINKO ELECTRIC INDUSTRIES CO., LTD.

(21) Appl. No.: 12/704,709

(22) Filed: Feb. 12, 2010

(30) Foreign Application Priority Data
Feb. 20, 2009 (JP) NO. 2009-037305

(51) Int. Cl. H01L 23/522; H01L 21/60

(52) U.S. Cl. 257/700; 438/124; 257/E21.506; 257/E23.142

(57) ABSTRACT

A semiconductor device includes an electronic component having a pad surface on which an electrode pad is formed, and having a back surface opposite the pad surface, a sealing resin disposed to cover side faces of the electronic component while exposing the pad surface at a first surface thereof and the back surface at a second surface thereof, a multilayer interconnection structure including insulating layers stacked one over another and interconnection patterns, having an upper surface thereof being in contact with the first surface, the electrode pad, and the pad surface, and having a periphery thereof situated outside a periphery of the sealing resin, and another pad disposed on the upper surface of the multilayer interconnection structure outside the periphery of the sealing resin, wherein the interconnection patterns include a first interconnection pattern directly connected to the electrode pad and a second interconnection pattern directly connected to said another pad.

### BACKGROUND OF THE INVENTION

1. Field of the Invention

The disclosures herein generally relate to semiconductor devices and methods of manufacturing semiconductor devices, and particularly relate to a semiconductor device and a method of manufacturing a semiconductor device that includes a wiring substrate and electronic components mounted on the wiring substrate.

2. Description of the Related Art

A certain type of semiconductor device achieves high-density implementation of electronic components by stacking the electronic components in a multilayer structure on a wiring substrate.

FIG. 1 is a cross-sectional view of a related-art semiconductor device. A semiconductor device 200 illustrated in FIG. 1 includes a wiring substrate 201, a first electronic component 202, and a second electronic component 203. The wiring substrate 201 includes a substrate 211, pads 213 and 214, and external connection pads 215.

The substrate 211 includes a plurality of insulating layers (not shown) stacked in a multilayer structure, and further includes interconnection patterns (not shown) formed between the insulating layers to electrically connect the pads 213 and/or 214 to the external connection pads 215.

The pads 213 and 214 are disposed on an upper surface 211A of the substrate 211. The external connection pads 215 are disposed on a lower surface 2118 of the substrate 211.

The first electronic component 202 is situated over the pad 213. The first electronic component 202 has an electrode pad 217 that is connected to a bump 205. The first electronic component 202 is electrically connected to the pad 213 via the bump 205 (e.g., solder bump or Au bump). In other words, the first electronic component 202 is flip-chip mounted to the wiring substrate 201. The first electronic component 202 may be a semiconductor chip.

The second electronic component 203 is adhesively connected to the first electronic component 202. The second electronic component 203 has an electrode pad 218 that is connected to a metal wire 206. The second electronic component 203 is electrically connected to the pad 214 via the metal wire 206. In other words, the second electronic component 203 is connected to the wiring substrate 201 through wire bonding. The second electronic component 203 may be a semiconductor chip (see Japanese Patent Application Publication No. 2002-83921, for example).

The related-art semiconductor device 200 achieves high-density implementation of electronic components. In this configuration, the first electronic component 202 is electrically connected to the wiring substrate 201 via the bump 205. This results in the size of the semiconductor device 200 being large in a thickness direction (i.e., height direction).

Further, the related-art semiconductor device 200 may not be able to secure a sufficient area size for adhesive connection when the surface area size of the second electronic component 203 is larger than the surface area size of the first electronic component 202 (i.e., when a large portion of the second electronic component 203 does not overlap the first electronic component 202). This gives rise to a problem in that the second electronic component 203 may not be fixedly mounted on the first electronic component 202 in a stable manner.

Accordingly, it may be desirable to provide a semiconductor device and a method of producing a semiconductor device for which the size of the semiconductor device in a thickness direction can be reduced, and the second electronic component larger in surface area size than the first electronic component can be fixedly mounted on the first electronic component in a stable manner.

### SUMMARY OF THE INVENTION

It is a general object of the present invention to provide a semiconductor device and a method of producing a semiconductor device that substantially eliminate one or more problems caused by the limitations and disadvantages of the related art.

According to one aspect, a semiconductor device includes a first electronic component having an electrode pad forming surface on which a first electrode pad is formed, and having a back surface opposite the electrode pad forming surface; a sealing resin having a first surface and a second surface, the sealing resin being disposed to cover side faces of the first electronic component while exposing the electrode pad forming surface at the first surface and the back surface at the second surface; a multilayer interconnection structure including insulating layers stacked one over another and interconnection patterns, the multilayer interconnection structure having an upper surface thereof being in contact with the first surface of the sealing resin, the first electrode pad, and the electrode pad forming surface, and the multilayer interconnection structure having a periphery thereof situated outside a periphery of the sealing resin; and another pad disposed on the upper surface of the multilayer interconnection structure outside the periphery of the sealing resin, wherein the interconnection patterns of the multilayer interconnection structure include a first interconnection pattern directly connected to the first electrode pad and a second interconnection pattern directly connected to said another pad.

According to another aspect, a method of manufacturing a semiconductor device includes a metal film forming step of forming, on a first surface of a support member, a metal film having a hole that exposes the first surface of the support member; a first electronic component mounting step of mounting the first electronic component having an electrode pad forming surface on which a first electrode pad is formed, and having a back surface opposite the electrode pad forming surface, by adhesively bonding the back surface of the first electronic component to the first surface of the support member that is exposed through the hole; a sealing resin providing step of providing a sealing resin that seals the first electronic component in the hole; a multilayer interconnection structure forming step of forming a multilayer interconnection structure including interconnection patterns and insulating layers stacked one over another on the first electrode pad, on the electrode pad forming surface, on the metal film, and on the sealing resin, the multilayer interconnection structure having a periphery thereof situated outside a periphery of the sealing resin; a support member removal step of removing the support member after the multilayer interconnection structure forming step; and a pad forming step of forming another pad by patterning the metal film after the support member removal step, wherein the multilayer interconnection structure forming step forms a first interconnection pattern that is directly connected to the first electrode pad, and forms a second interconnection pattern that is connected to said another pad.

According to at least one embodiment, the size of the semiconductor device in the thickness direction is reduced. Further, a second electronic component having a larger surface size than the first electronic component may be fixedly mounted to the first electronic component in a stable manner.

### BRIEF DESCRIPTION OF THE DRAWINGS

Other objects and further features of the present invention will be apparent from the following detailed description when read in conjunction with the accompanying drawings, in which:

FIG. 1 is a cross-sectional view of a related-art semiconductor device;

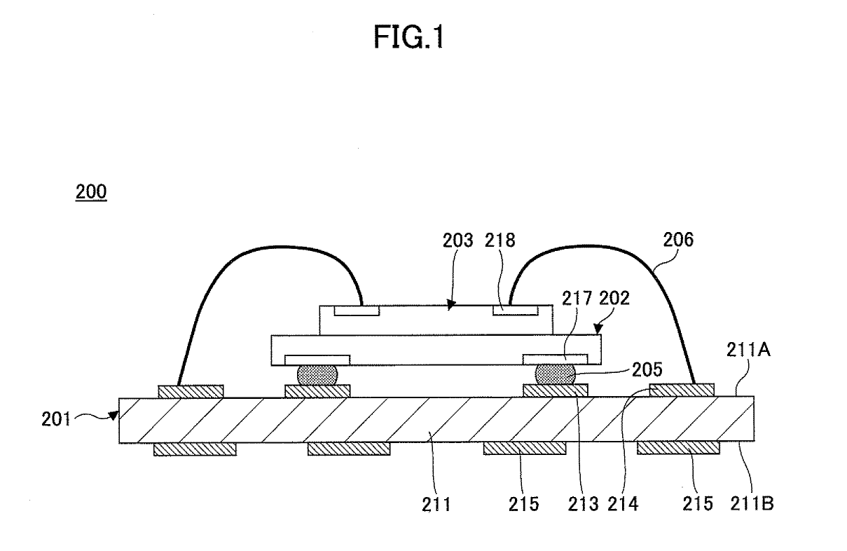

FIG. 2 is a cross-sectional view of a semiconductor device according to a first embodiment;

FIG. 3 is a cross-sectional view of a semiconductor device according to a variation of the first embodiment;

FIG. 4 is a drawing illustrating a first step of manufacturing the semiconductor device according to the first embodiment;

FIG. 5 is a drawing illustrating a second step of manufacturing the semiconductor device according to the first embodiment;

FIG. 6 is a drawing illustrating a third step of manufacturing the semiconductor device according to the first embodiment;

FIG. 7 is a drawing illustrating a fourth step of manufacturing the semiconductor device according to the first embodiment;

FIG. 8 is a drawing illustrating a fifth step of manufacturing the semiconductor device according to the first embodiment;

FIG. 9 is a drawing illustrating a sixth step of manufacturing the semiconductor device according to the first embodiment;

FIG. 10 is a drawing illustrating a seventh step of manufacturing the semiconductor device according to the first embodiment;

FIG. 11 is a drawing illustrating an eighth step of manufacturing the semiconductor device according to the first embodiment;

FIG. 12 is a drawing illustrating a ninth step of manufacturing the semiconductor device according to the first embodiment;

FIG. 13 is a drawing illustrating a tenth step of manufacturing the semiconductor device according to the first embodiment;

FIG. 14 is a drawing illustrating an eleventh step of manufacturing the semiconductor device according to the first embodiment;

FIG. 15 is a drawing illustrating a twelfth step of manufacturing the semiconductor device according to the first embodiment;

FIG. 16 is a drawing illustrating a thirteenth step of manufacturing the semiconductor device according to the first embodiment;

FIG. 17 is a drawing illustrating a fourteenth step of manufacturing the semiconductor device according to the first embodiment;

FIG. 18 is a drawing illustrating a fifteenth step of manufacturing the semiconductor device according to the first embodiment;

FIG. 19 is a drawing illustrating a sixteenth step of manufacturing the semiconductor device according to the first embodiment;

FIG. 20 is a drawing illustrating a seventeenth step of manufacturing the semiconductor device according to the first embodiment;

FIG. 21 is a drawing illustrating an eighteenth step of manufacturing the semiconductor device according to the first embodiment;

FIG. 22 is a drawing illustrating a nineteenth step of manufacturing the semiconductor device according to the first embodiment;

FIG. 23 is a drawing illustrating a twentieth step of manufacturing the semiconductor device according to the first embodiment;

FIG. 24 is a drawing illustrating a twenty-first step of manufacturing the semiconductor device according to the first embodiment;

FIG. 25 is a cross-sectional view of a semiconductor device according to a second embodiment;

FIG. 26 is a cross-sectional view of a semiconductor device according to a variation of the second embodiment; and

FIG. 27 is a drawing for illustrating actual thickness relationships between a first electronic component, a sealing resin, pads, and a multilayer interconnection structure.

### DESCRIPTION OF THE PREFERRED EMBODIMENTS

In the following, embodiments of the present invention will be described with reference to the accompanying drawings.

### First Embodiment

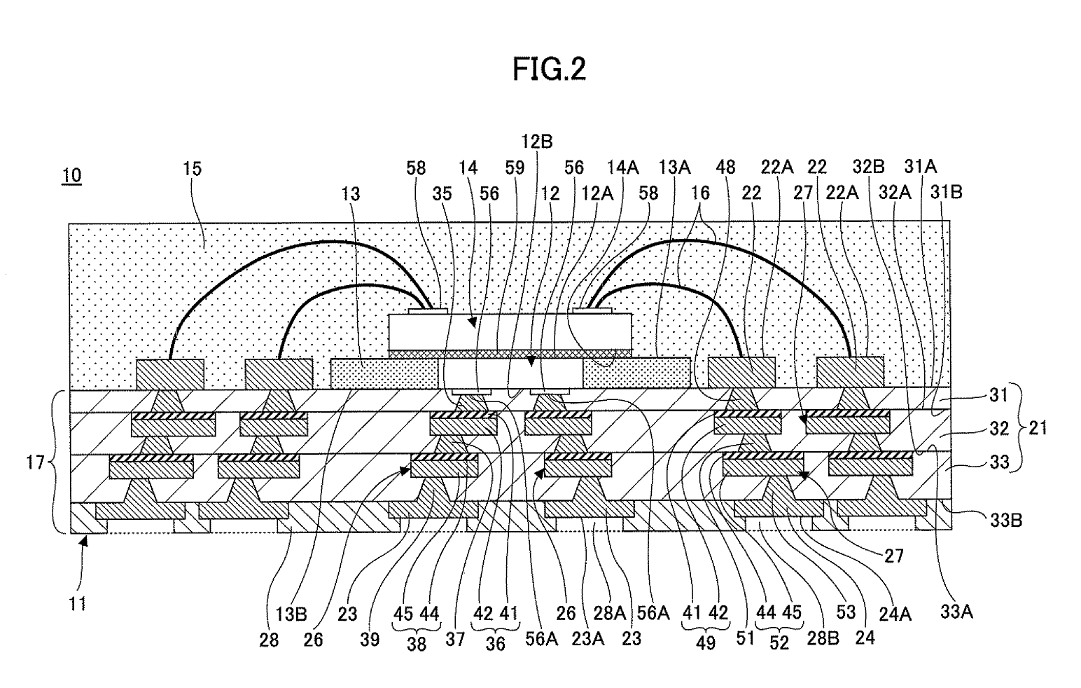

FIG. 2 is a cross-sectional view of a semiconductor device according to a first embodiment.

A semiconductor device 10 illustrated in FIG. 2 includes a wiring substrate 11, a first electronic component 12, sealing resins 13 and 15, and a second electronic component 14.

The wiring substrate 11 includes a multilayer interconnection structure 17 and pads 22. The multilayer interconnection structure 17 includes a multilayer structure 21, first external connection pads 23, second external connection pads 24, first interconnection patterns 26, second interconnection patterns 27, and a solder resist layer 28. The first interconnection patterns 26 and the second interconnection patterns 27 may be connected to each other in the multilayer interconnection structure 17.

The multilayer structure 21 is situated to face the lower surface (i.e., first surface) of the sealing resin 13, electrode pads 56 formed on the electronic component 12, and an electrode pad forming surface 12B of the electronic component 12. The electrode pads 56 and the electrode pad forming surface 12B will be described later. The upper surface of the multilayer structure 21 that is in contact with the sealing resin 13 (to be more specific, an upper surface 31A of an insulating layer 31 which will be described later) has an area size that is larger than the area size of a lower surface 13B of the sealing resin 13. With this arrangement, the peripheral edge of the multilayer structure 21 is situated outside the peripheral edge of the sealing resin 13.

The multilayer structure 21 includes insulating layers 31 through 33 stacked in a multilayer structure. The insulating layer 31 is situated between the insulating layer 32 and each of the first electronic component 12, the sealing resin 13, and the pads 22. The upper surface 31A of the insulating layer 31 is in contact with the electrode pad forming surface 12B of the first electronic component 12, the lower surface 13B of the sealing resin 13, and the lower surfaces of the pads 22. A lower surface 31B of the insulating layer 31 is in contact with an upper surface 32A of the insulating layer 32. The insulating layer 31 is the topmost layer of the insulating layers 31 through 33. An insulating resin (e.g., epoxy resin) having photosensitivity, for example, may be used as the insulating layer 31. When an insulating resin having photosensitivity is used as the insulating layer 31, the thickness of the insulating layer 31 may be 3 micrometers, for example.

The insulating layer 32 is disposed on an upper surface 33A of the insulating layer 33. An insulating resin (e.g., epoxy resin) having photosensitivity, for example, may be used as the insulating layer 32. When an insulating resin having photosensitivity is used as the insulating layer 32, the thickness of the insulating layer 32 may be about 5 micrometers, for example.

The insulating layer 33 is situated beneath a lower surface 32B of the insulating layer 32. An insulating resin (e.g., epoxy resin) having photosensitivity, for example, may be used as the insulating layer 33. When an insulating resin having photosensitivity is used as the insulating layer 33, the thickness of the insulating layer 33 may be about 10 micrometers, for example.

The first external connection pads 23 are formed on a lower surface 33B of the insulating layer 33 in an area situated directly below the first electronic component 12, i.e., at a center of the lower surface 33B of the insulating layer 33. The first external connection pads 23 are connected to the first interconnection patterns 26. The first external connection pads 23 are electrically connected to the first electronic component 12 through the first interconnection patterns 26. The first external connection pads 23 have connection surfaces 23A on which external connection terminals (not shown) are disposed.

The second external connection pads 24 are formed on the lower surface 33B of the insulating layer 33. The second external connection pads 24 are disposed on the lower surface 33B of the insulating layer 33 such as to surround the first external connection pads 23. The second external connection pads 24 are connected to the second interconnection patterns 27. The second external connection pads 24 have connection surfaces 24A on which external connection terminals (not shown) are disposed.

The first and second external connection pads 23 and 24 are provided for electrical connection to a mounting board (not shown) through external connection terminals (not shown) when the semiconductor device 10 is connected to the mounting board such as a mother board. The material of the first and second external connection pads 23 and 24 may be Cu, for example.

The first interconnection patterns 26 are embedded in the multilayer structure of the insulating layers 31 through 33, and include vias 35, 37, and 39 and interconnections 36 and 38. A via 35 is formed to penetrate through the insulating layer at the position where an electrode pad 56 is formed on the first electronic component 12. The top surface (i.e., first connection surface) of the via is directly connected to the electrode pad 56. The via 35 is the part of the first interconnection pattern 26 that corresponds to the first connection surface. Cu may be used as the material of the via 35.

In this manner, the top surface of the via 35 that constitutes part of the first interconnection pattern 26 is directly connected to the electrode pad 56 formed on the first electronic component 12. This arrangement makes it possible to establish an electrical connection between the first electronic component and the wiring substrate without using a bump. In this manner, the size of the semiconductor device 10 in the thickness direction can be reduced.

The interconnection 36 includes a first metal layer 41 and a second metal layer 42. The first metal layer 41 is formed on the lower surface 31B of the insulating layer 31 and on the bottom surface of the via 35. The first metal layer 41 may be a Ti layer. When a Ti layer is used as the first metal layer 41, the thickness of the first metal layer 41 may be 0.03 micrometers, for example.

The second metal layer 42 is situated beneath the first metal layer 41. The second metal layer 42 may be a Cu layer. When a Cu layer is used as the second metal layer 42, the thickness of the second metal layer 42 may be 3.0 micrometers, for example.

The interconnection 36 having the above-described structure is connected to the via 35, and is electrically connected to the first electronic component 12 through the via 35. The interconnection 36 is a fine interconnection line. The width of the interconnection 36 may be 1 to 5 micrometers, for example.

A via 37 is formed to penetrate through the insulating layer 32 between the position of the interconnection 36 and the position of the interconnection 38. The top end of the via 37 is connected to the interconnection 36 (to be more specific, to the lower surface of the second metal layer 42 that is part of the interconnection 36). In this manner, the via 37 is electrically connected to the via 35 through the interconnection 36. Cu may be used as the material of the via 37.

The interconnection 38 includes a first metal layer 44 and a second metal layer 45. The first metal layer 44 is formed on the lower surface 32B of the insulating layer 32 and on the bottom surface of the via 37. The first metal layer 44 may be a Ti layer. When a Ti layer is used as the first metal layer 44, the thickness of the first metal layer 44 may be 0.03 micrometers, for example.

The second metal layer 45 is situated beneath the first metal layer 44. The second metal layer 45 may be a Cu layer. When a Cu layer is used as the second metal layer 45, the thickness of the second metal layer 45 may be 3.0 micrometers, for example.

The interconnection 38 having the above-described structure is connected to the via 37, and is electrically connected to the interconnection 36 through the via 37. The interconnection 38 is an interconnection line that is wider than the interconnection 36. The width of the interconnection 38 may be 5 to 10 micrometers, for example.

A via 39 is formed to penetrate through the insulating layer 33 between the position of the interconnection 38 and the position of a first external connection pad 23. The top end of the via is connected to the interconnection 38 (to be more specific, to the lower surface of the second metal layer 45 that is part of the interconnection 38). The bottom surface (i.e., second connection surface) of the via 39 is connected to the first external connection pad 23. In this manner, the via 39 electrically connects between the interconnection 38 and the first external connection pad 23. Cu may be used as the material of the via 39.

The first interconnection pattern 26 having the above-described configuration provides an electrical coupling between the first electronic component 12 and the first external connection pad 23.

The second interconnection patterns 27 are embedded in the multilayer structure of the insulating layers 31 through 33, and include vias 48, 51, and 53 and interconnections 49 and 52. A via 48 is formed to penetrate through the insulating layer 31 at the position where a pad 22 is situated. The top surface of the via 48 is connected to the pad 22. Cu may be used as the material of the via 48.

The interconnection 49 includes a first metal layer 41 and a second metal layer 42. The first metal layer 41 is formed on the lower surface 31B of the insulating layer 31 and on the bottom surface of the via 48. The first metal layer 41 may be a Ti layer. When a Ti layer is used as the first metal layer 41, the thickness of the first metal layer 41 may be 0.03 micrometers, for example.

The second metal layer 42 is situated beneath the first metal layer 41. The second metal layer 42 may be a Cu layer. When a Cu layer is used as the second metal layer 42, the thickness of the second metal layer 42 may be 3.0 micrometers, for example.

The interconnection 49 having the above-described structure is connected to the via 48, and is electrically connected to the pad 22 through the via 48. The interconnection 49 is a fine interconnection line. The width of the interconnection 49 may be 1 to 5 micrometers, for example.

A via 51 is formed to penetrate through the insulating layer 32 between the position of the interconnection 49 and the position of the interconnection 52. The top end of the via 51 is connected to the interconnection 49 (to be more specific, to the lower surface of the second metal layer 42 that is part of the interconnection 49). In this manner, the via 51 is electrically connected to the via 48 through the interconnection 49. Cu may be used as the material of the via 51.

The interconnection 52 includes a first metal layer 44 and a second metal layer 45. The first metal layer 44 is formed on the lower surface 32B of the insulating layer 32 and on the bottom surface of the via 51. The first metal layer 44 may be a Ti layer. When a Ti layer is used as the first metal layer 44, the thickness of the first metal layer 44 may be 0.03 micrometers, for example.

The second metal layer 45 is situated beneath the first metal layer 44. The second metal layer 45 may be a Cu layer. When a Cu layer is used as the second metal layer 45, the thickness of the second metal layer 45 may be 3.0 micrometers, for example.

The interconnection 52 having the above-described structure is connected to the via 51, and is electrically connected to the interconnection 49 through the via 51. The interconnection 52 is an interconnection line that is wider than the interconnection 49. The width of the interconnection 52 may be 5 to 10 micrometers, for example.

A via 53 is formed to penetrate through the insulating layer 33 between the position of the interconnection 52 and the position of a second external connection pad 24. The top end of the via is connected to the interconnection 52 (to be more specific, to the lower surface of the second metal layer 45 that is part of the interconnection 52). The bottom of the via 53 is connected to the second external connection pad 24. In this manner, the via 53 electrically connects between the interconnection 52 and the second external connection pad 24. Cu may be used as the material of the via 53.

The second interconnection pattern 27 having the above-described configuration provides an electrical coupling between the pad 22 and the second external connection pad 24. Further, the second interconnection pattern 27 is electrically connected to the second electronic component 14 via the pad 22 and a metal wire 16.

The solder resist layer 28 is formed on the lower surface 33B of the insulating layer 33. The solder resist layer 28 has an opening 28A to expose a connection surface 23A of the first external connection pad 23 and an opening 28B to expose a connection surface 24A of the second external connection pad 24.

A plurality of pads 22 are disposed on the upper surface 31A of the insulating layer 31 (i.e., on the first surface of the multilayer structure 21). The pads 22 are arranged near the periphery of the upper surface 31A of the insulating layer 31 to surround the sealing resin 13, i.e., arranged on the upper surface 31A of the insulating layer 31 outside the area where the sealing resin 13 is disposed. The pads 22 are connected to one end of the metal wires 16 (e.g., Au wires). The pads 22 are electrically connected to the second electronic component 14 via the metal wires 16. Further, the pads 22 are connected to the second interconnection patterns 27. In this manner, the pads 22 electrically connect between the second electronic component 14 and the second interconnection patterns 27. The thickness of the pads 22 is set substantially equal to the thickness of the sealing resin 13. The shape of each pad 22 may be a pillar shape (e.g., cylindrical shape). When the shape of each pad 22 is cylindrical, the diameter of each pad 22 may be 100 to 300 micrometers, for example. The thickness of the pads 22 may be 200 to 300 micrometers, for example. Cu may be used as the material of the pads 22.

The first electronic component 12 is an electronic component having a thin plate shape. The first electronic component 12 has a plurality of electrode pads 56 (i.e., first electrode pads), the electrode pad forming surface 12B on which the electrode pads 56 are formed, and a back surface 12A opposite the electrode pad forming surface 12B.

Each of the electrode pads 56 has a connection surface 56A that is a flat surface. The first electronic component 12 is disposed at the center of the upper surface 31A of the insulating layer 31 such that the top surfaces of the vias 35 (i.e., the portion of the first interconnection patterns 26 exposed at the upper surface of the multilayer structure 21) come in contact with the connection surfaces 56A of the electrode pads 56. In this manner, the electrode pads 56 of the first electronic component 12 are directly connected to the first interconnection patterns 26 (i.e., to the top end of the vias 35, to be more specific) embedded in the multilayer structure of the insulating layers 31 through 33.

In this manner, the electrode pads 56 of the first electronic component 12 and the first interconnection patterns 26 are directly connected to each other. With this arrangement, the size of the semiconductor device 10 in the thickness direction can be reduced, compared with the case in which the electrode pads 56 of the first electronic component 12 are connected to the first interconnection patterns 26 through bumps.

The first electronic component 12 is electrically connected to the first external connection pads 23 through the first interconnection patterns 26. The back surface 12A of the first electronic component 12 is a flat surface. The area size of the back surface 12A of the first electronic component 12 is smaller than the area size of a surface 14A of the second electronic component 14 that faces the back surface 12A. The thickness of the first electronic component 12 is substantially equal to the thickness of the sealing resin 13. The thickness of the first electronic component 12 may be 200 to 300 micrometers, for example.

The first electronic component 12 having the above-described configuration may be a semiconductor chip that is a CPU.

The sealing resin 13 is situated at the center of the upper surface 31A of the insulating layer 31 such as to seal the circumference (i.e., side faces) of the first electronic component 12. The sealing resin 13 is arranged to cover the side faces of the first electronic component 12. The sealing resin 13 seals the side faces of the first electronic component 12. The peripheral edges of the sealing resin 13 are situated outside the peripheral edges of the second electronic component 14. The upper surface 13A (i.e., second surface) of the sealing resin 13 is a flat surface that exposes the back surface 12A of the first electronic component 12. The upper surface 13A of the sealing resin 13 is configured to be substantially flush with the back surface 12A of the first electronic component 12 and the upper surfaces 22A of the pads 22. In other words, the upper surface 13A of the sealing resin 13, the back surface 12A of the first electronic component 12, and the upper surfaces 22A of the pads are coplanar. The upper surface 13A of the sealing resin 13 and the back surface 12A of the first electronic component 12 together form a single surface that is adhesively connected to the second electronic component 14, which has a surface 14A facing the first electronic component 12 and has an area size that is larger than the area size of the back surface 12A of the first electronic component 12.

In this manner, the sealing resin 13 is provided around the first electronic component 12 to cover the side faces of the first electronic component 12, such that the upper surface 13A of the sealing resin 13 is substantially flush with the back surface 12A of the first electronic component 12 and the upper surfaces 22A of the pads 22. With this configuration, the second electronic component 14 having a larger surface size than the first electronic component 12 can be fixedly mounted to the back surface 12A of the first electronic component 12 and the upper surface 13A of the sealing resin 13.

The lower surface 13B (i.e., first surface) of the sealing resin 13 is flat, and exposes the electrode pad forming surface 12B of the first electronic component 12.

A mold resin may be used as the sealing resin 13 having the above-described configuration. An epoxy resin may be used as the material of the mold resin. The thickness of the sealing resin 13 is substantially equal to the thickness of the pads 22 and the first electronic component 12. The thickness of the sealing resin 13 may be 200 to 300 micrometers, for example.

The second electronic component 14 has a larger surface size than the first electronic component 12. The second electronic component 14 has a plurality of electrode pads 58. The second electronic component 14 is adhesively connected to the back surface 12A of the first electronic component 12 and to the upper surface 13A of the sealing resin 13 via an adhesive agent 59 (e.g., die attach film) disposed on a surface 14A of the second electronic component 14 (i.e., the surface of the second electronic component 14 opposite the surface on which the electrode pads 58 are formed). The electrode pads 58 are connected to one end of the metal wires 16. With this configuration, the second electronic component 14 is electrically connected to the wiring substrate 11 via the metal wires 16.

The second electronic component 14 having the above-described configuration may be a semiconductor chip that is a memory.

The sealing resin 15 is situated over the upper surface 31A of the insulating layer 31 to cover the sealing resin 13, the second electronic component 14, the metal wires 16, and the pads 22. The sealing resin 15 seals the second electronic component 14 and the metal wires 16. A mold resin may be used as the sealing resin 15. An epoxy resin may be used as the material of the mold resin.

According to the semiconductor device of the present embodiment, the top surface of the via that constitutes part of the first interconnection pattern 26 is directly connected to the electrode pad 56 formed on the first electronic component 12. Further, the upper surfaces 22A of the pads 22, the back surface 12A of the first electronic component 12, and the upper surface 13A of the sealing resin 13 situated on the multilayer structure 21 are flush with each other. This arrangement makes it possible to establish an electrical connection between the first electronic component 12 and the wiring substrate 11 without using a bump. Accordingly, the size of the semiconductor device 10 in the thickness direction can be reduced.

Moreover, the sealing resin 13 is disposed around the first electronic component 12 to seal the side faces of the first electronic component 12. Provision is made such that the upper surface 13A of the sealing resin 13, the back surface 12A of the first electronic component 12, and the upper surfaces 22A of the pads 22 are flush with each other. With this configuration, the second electronic component 14 having a larger surface size than the first electronic component 12 can be fixedly mounted (i.e., adhesively connected) to the back surface 12A of the first electronic component 12 and the upper surface 13A of the sealing resin 13.

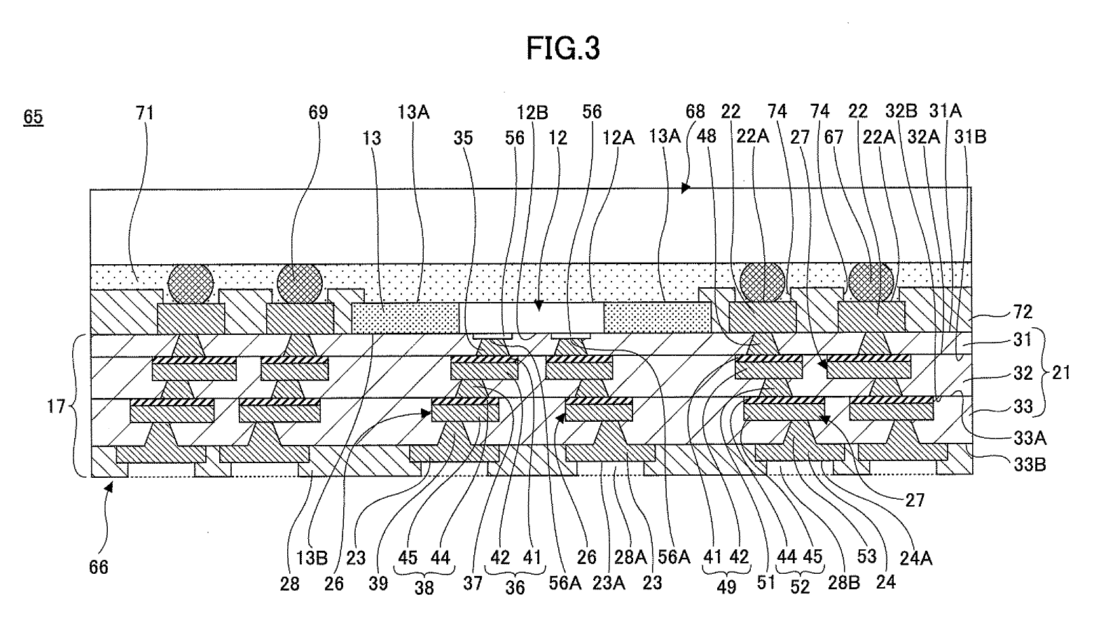

FIG. 3 is a cross-sectional view of a semiconductor device according to a variation of the first embodiment. In FIG. 3, the same elements as those of the semiconductor device 10 of the first embodiment are referred to by the same numerals.

A semiconductor device 65 illustrated in FIG. 3 according to the variation of the first embodiment includes a first electronic component 12, a sealing resin 13, a wiring substrate 66, a second electronic component 68, internal connection terminals 69, and an underfill resin 71.

The wiring substrate 66 is configured substantially in the same fashion as the wiring substrate 11, except that a solder resist layer 72 is provided in addition to the configuration of the wiring substrate 11 used in the semiconductor device 10 of the first embodiment.

The solder resist layer 72 is formed on the upper surface 31A of the insulating layer 31. The solder resist layer 72 has openings 74 that expose the upper surfaces 22A of the pads 22.

The second electronic component 68 is situated over the upper surface of the wiring substrate 66. The second electronic component 68 is electrically connected to the internal connection terminals 69. The second electronic component 68 is electrically connected (flip-chip connected) to the wiring substrate 66 through the internal connection terminals 69. The second electronic component 68 may be a semiconductor chip that is a memory.

The internal connection terminals 69 are disposed on the upper surfaces 22A of the pads 22 exposed through the openings 74, and are electrically connected to the second electronic component 68. Solder bumps may be used as the internal connection terminals 69.

The underfill resin 71 is disposed to fill the gap between the second electronic component 68 and the wiring substrate 66.

In the semiconductor device according to the variation of the first embodiment, the electrode pad 56 formed on the first electronic component 12 is directly connected to the portion of the first interconnection pattern 26 that is exposed from the upper surface 31A of the insulating layer 31. Further, the second electronic component 68 is flip-chip connected to the pads 22. With this arrangement, the size of the semiconductor device 65 in the thickness direction can be reduced, compared with the case in which the second electronic component 68 is connected through wire bonding to the pads 22.

In place of the second electronic component 68, another semiconductor device (not shown) or another wiring substrate (not shown) may be provided, and may be electrically connected to the pads 22 through the internal connection terminals 69. In this case, solder balls may be used as the internal connection terminals 69.

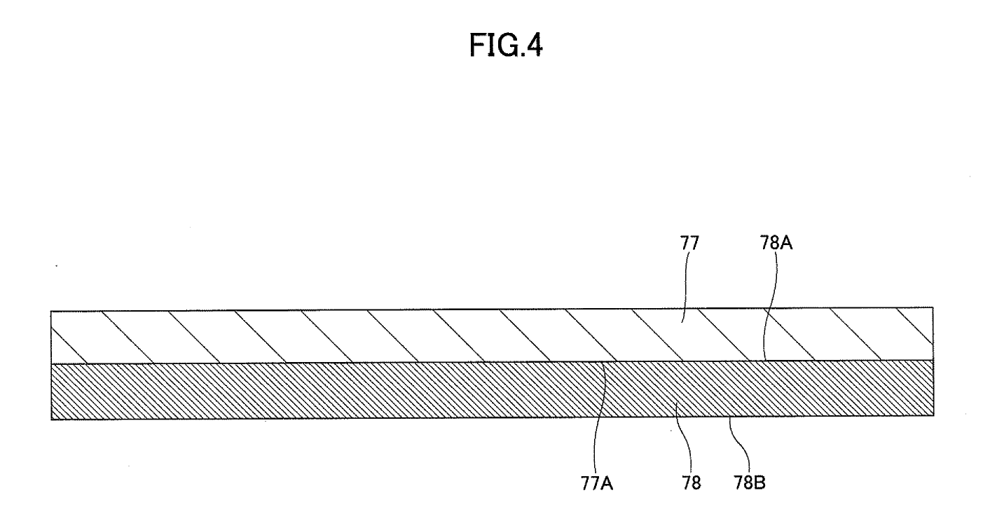

FIGS. 4 through 24 are drawings illustrating the steps of manufacturing the semiconductor device according to the first embodiment. In FIGS. 4 through 24, the same elements as those of the semiconductor device 10 of the first embodiment are referred to by the same numerals.

In the following, a description will be given of the method of manufacturing the semiconductor device 10 according to the first embodiment by referring to FIG. 4 through FIG. 24. In the process step illustrated in FIG. 4, a metal film 78 that covers a lower surface 77A (i.e., first surface) of a support member 77 is formed. The support member 77 may be a resin substrate (e.g., glass epoxy substrate), a metal substrate (e.g., SUS plate), a glass plate, or a silicon substrate. The thickness of the support member 77 may be 500 to 1000 micrometers when a silicon substrate is used as the support member 77. In the following, a description will be given of an example in which a silicon substrate is used as the support member 77.

The metal film 78 will turn into the pads 22. A lower surface 78B of the metal film 78 is flat. The thickness of the metal film 78 is substantially equal to the thickness of the first electronic component 12. A Cu film (with a thickness of 500 micrometers, for example) may be used as the metal film 78, for example. The metal film 78 that is a Cu film may be formed by use of plating. Specifically, electroless plating may be employed to form an electroless Cu film on the lower surface 77A of the support member 77. Electro plating is then employed by using the electroless Cu film as a power feeding layer to form an electro Cu plating film on the lower surface of the electroless Cu plating film.

The metal film 78 may alternatively be formed by adhesively attaching (i.e., attaching through an adhesive agent) a metal foil such as a Cu foil or a metal plate such as a Cu plate.

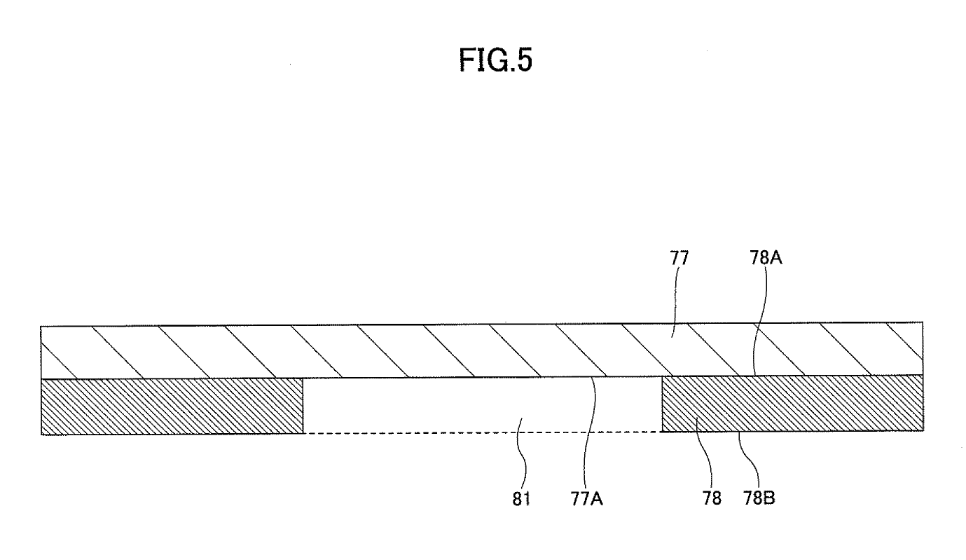

In the process step illustrated in FIG. 5, the metal film 78 is etched at the positions where the first electronic component 12 and the sealing resin 13 are to be disposed. A hole 81 is thus formed through the metal film 78. The process steps illustrated in FIG. 4 and FIG. 5 constitute a metal film forming step.

Specifically, a resist film (not shown) having an opening that exposes the lower surface 78B of the metal film 78 is formed on the lower surface 78B of the metal film 78 illustrated in FIG. 4, for example. Wet etching (or dry etching) is then performed by using this resist film as a mask to form the hole 81.

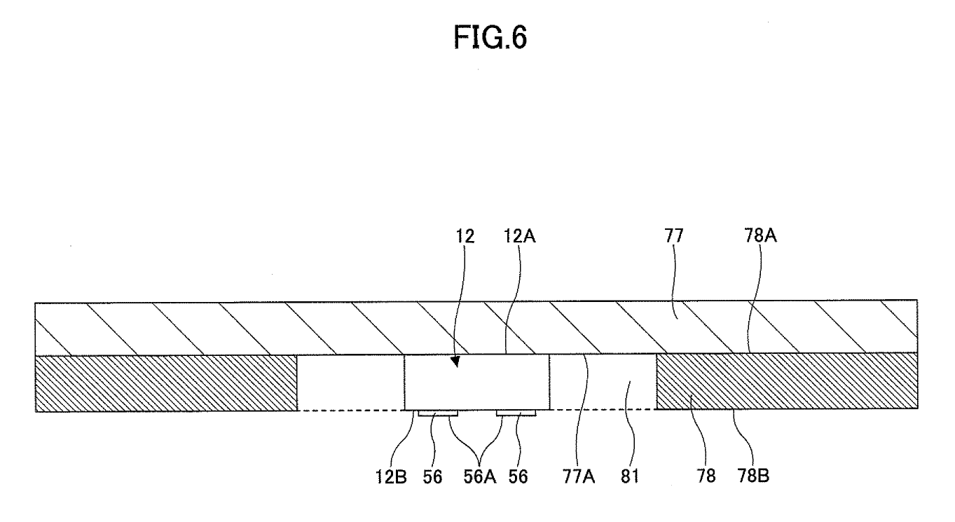

In the process step illustrated in FIG. 6, the first electronic component 12 having substantially the same thickness as the metal film 78 is adhesively connected to the lower surface 77A of the support member 77 that is exposed through the hole 81. This step is referred to as a first electrode component mounting step.

The adhesive bonding of the first electronic component 12 to the lower surface 77A of the support member 77 is performed such that the electrode pad forming surface 12B of the first electronic component 12 is substantially flush with the lower surface 78B of the metal film 78. The adhesive bonding of the first electronic component 12 may utilize a die attach film (not shown), for example. The first electronic component 12 is not yet made into a thin plate at this stage. The thickness of the first electronic component 12 at this stage may be 500 micrometers, for example.

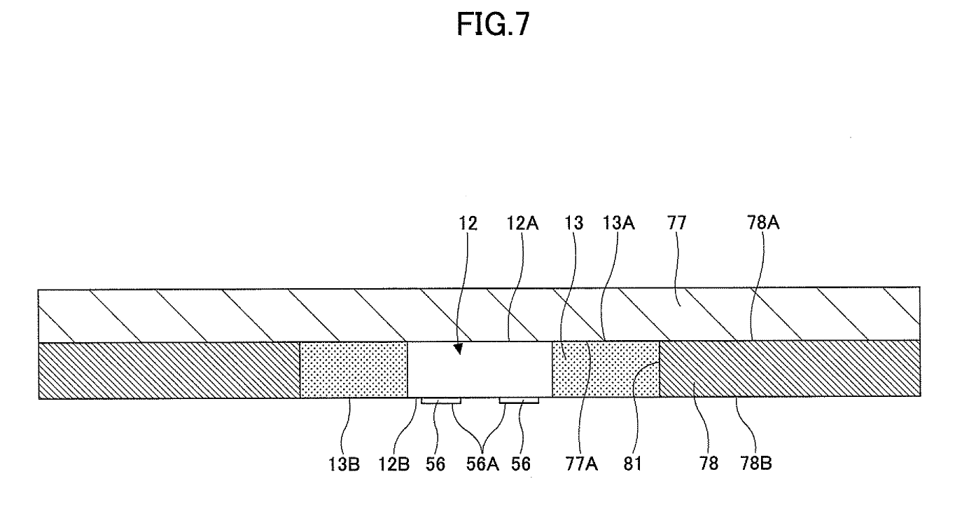

In the process step illustrated in FIG. 7, the sealing resin 13 is disposed to seal the first electronic component 12 in the hole 81 such that the lower surface 13B of the sealing resin 13 is substantially flush with the electrode pad forming surface 12B of the first electronic component 12 and the lower surface 78B of the metal film 78. This step is referred to as a sealing resin providing step.

In this step, the sealing resin 13 is disposed to fill the hole 81 in which the first electronic component 12 is situated while exposing the electrode pads 56 and the electrode pad forming surface 12B. The lower surface 13B of the sealing resin 13 is formed as a flat surface. The sealing resin 13 may be formed by a compression molding method that utilizes a metal mold, for example. The sealing resin 13 may be formed by resin potting, for example, if sufficient flatness is obtained.

An epoxy resin may be used as the material of the sealing resin 13. The thickness of the sealing resin 13 is substantially equal to the thickness of the first electronic component 12 and the thickness of the metal film 78 illustrated in FIG. 7. The thickness of the sealing resin 13 at this stage may be 500 micrometers, for example.

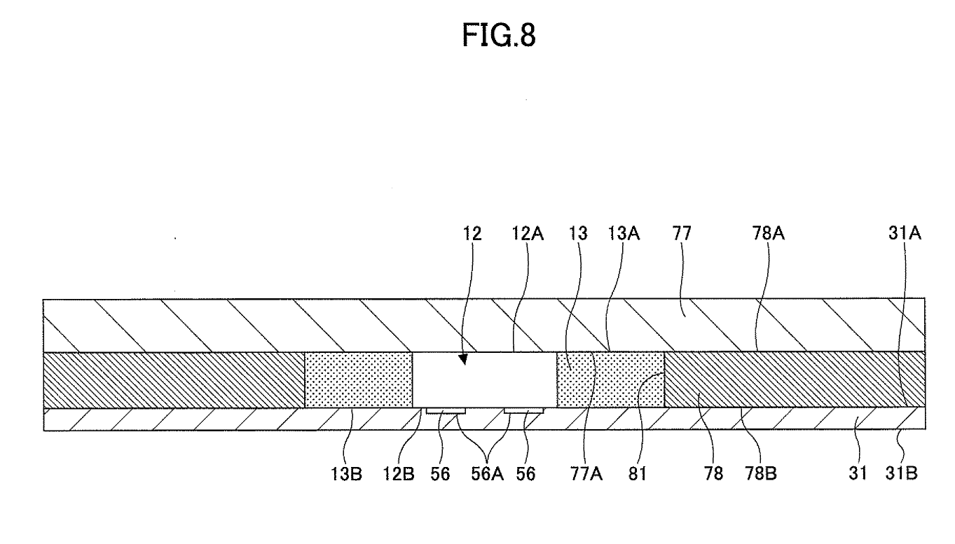

In the process step illustrated in FIG. 8, the insulating layer 31 is formed on the electrode pad forming surface 12B, the electrode pads 56, the lower surface 78B of the metal film 78, and the lower surface 13B of the sealing resin 13 to cover the electrode pads 56. The insulating layer 31 may be formed by laminating the connection surfaces 56A of the electrode pads 56, the lower surface 78B of the metal film 78, and the lower surface 13B of the sealing resin 13 with a photosensitive resin film (e.g., resin film made of an epoxy resin), for example. The thickness of the insulating layer 31 may be 3 micrometers, for example.

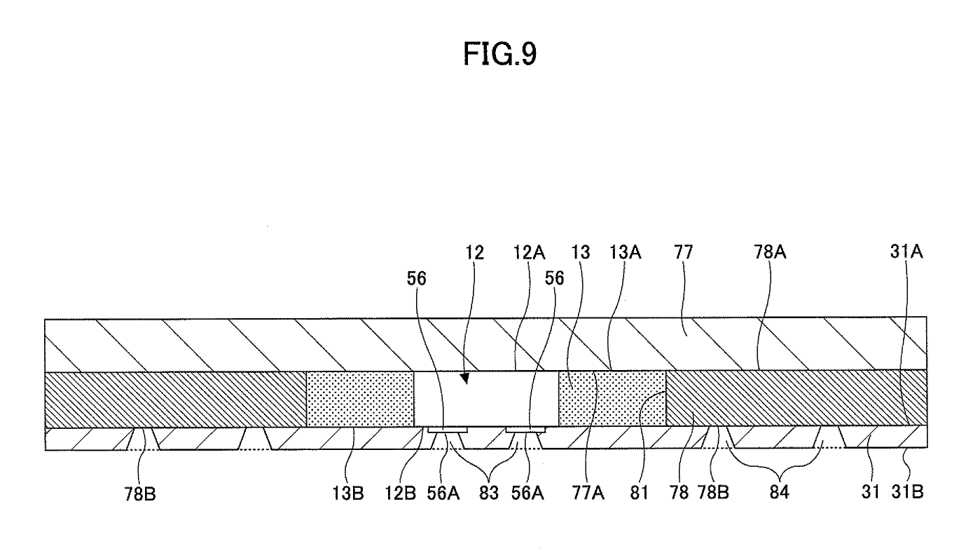

In the process step illustrated in FIG. 9, openings 83 to expose the connection surfaces 56A and openings 84 to expose the lower surface 785 of the metal film 78 are formed through the insulating layer 31 from below the lower surface 31B of the insulating layer 31. The openings 83 are formed through the insulating layer 31 at the positions where the vias 35 are to be formed such that the connection surfaces 56A serve as an end face. The openings 84 are formed through the insulating layer at the positions where the vias 48 are to be formed such that the lower surface 78B of the metal film 78 serves as an end face. Specifically, in the case of the insulating layer 31 being a photosensitive resin, the lower surface 31B of the insulating layer 31 is exposed to light through a photo mask that has openings to expose the lower surface 31B of the insulating layer 31 at the positions where the openings 83 and 84 are to be formed. The insulating layer 31 is then developed to form the openings.

The insulating layer 31 having the openings 83 and 84 may be formed by a method different from the one described above. In the case of the insulating layer 31 being a polyimide resin or epoxy resin that is not a photosensitive resin, for example, the insulating layer 31 having the openings 83 and 84 may be formed by using a laser process to shape the polyimide resin or epoxy resin at the positions where the openings 83 and 84 are to be formed.

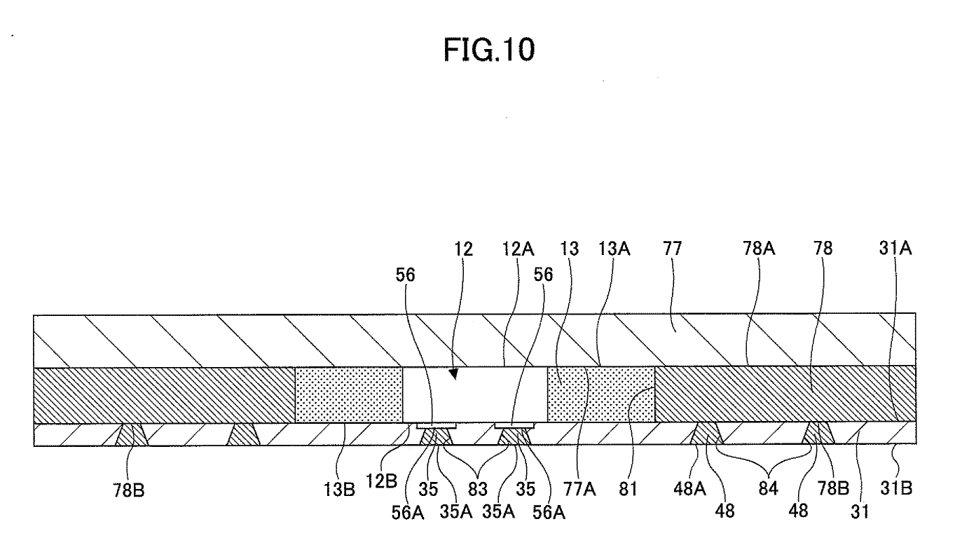

In the process step illustrated in FIG. 10, the vias 35 are formed to fill the openings 83 and directly connected to the electrode pads 56 of the first electronic component 12 (i.e., connected to the connection surfaces 56A of the electrode pads 56 to be more specific). Further, the vias 48 are formed to fill the openings 84 and connected to the metal film 78. The top surface (i.e., first connection surface) of the vias 35 is directly connected to the connection surface 56A of the electrode pads 56.

In this manner, the electrode pads 56 of the first electronic component 12 and the vias 35 (i.e., one of the elements constituting the first interconnection pattern 26) are directly connected to each other. With this arrangement, the size of the semiconductor device 10 in the thickness direction can be reduced, compared with the case in which the electrode pads 56 of the first electronic component 12 are connected to the first interconnection patterns 26 through bumps.

Further, the vias 35 and 48 are formed such that the lower surfaces 35A and 48A of the vias and 48 are substantially flush with the lower surface 31B of the insulating layer 31. Cu may be used as the material of the vias 35 and 48.

Specifically, electroless plating may be employed to form an electroless Cu plating film to cover the lower surface of the structure illustrated in FIG. 9 (inclusive of the end surfaces and sidewalls of the openings 83 and 84). Electro plating is then employed by using the electroless plating film as a power feeding layer to form an electro Cu plating film. After this, chemical mechanical polishing (CMP) is performed to remove the needless electroless Cu plating film and electro Cu plating film that are formed on the lower surface 31B of the insulating layer 31. In this manner, the vies 35 and 48 that have the lower surfaces 35A and 48A substantially flush with the lower surface 31B of the insulating layer 31 are formed.

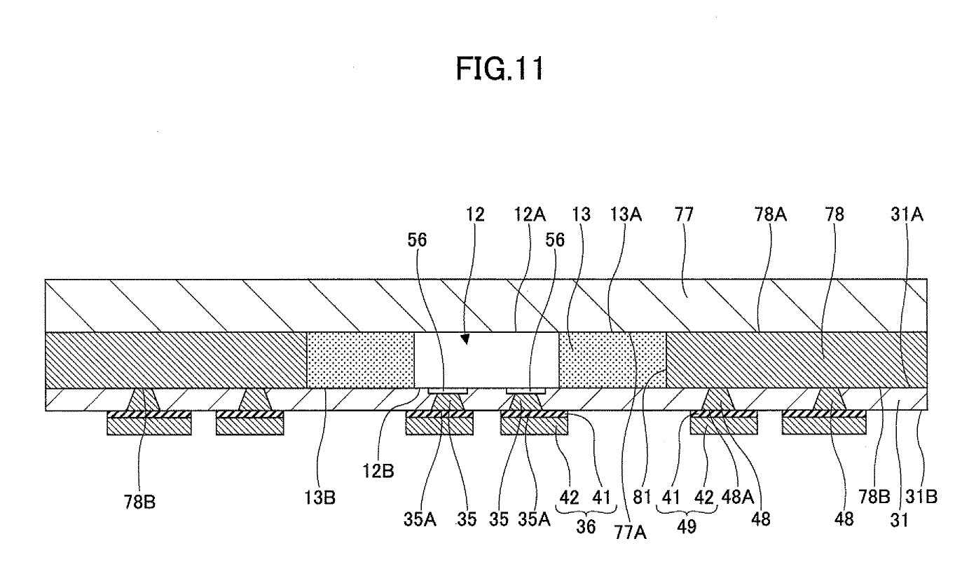

In the process step illustrated in FIG. 11, the interconnection 36 comprised of the first metal layer 41 and the second metal layer 42 is formed on the lower surface 35A of the via 35 and the lower surface 31B of the insulating layer 31. Further, the interconnection 49 comprised of the first metal layer 41 and the second metal layer 42 is formed on the lower surface 48A of the via 48 and the lower surface 31B of the insulating layer 31. The interconnections 36 and 49 are fine interconnection lines, the width of which may be 1 to 5 micrometers, for example. A Ti film (with a thickness of 0.03 micrometers, for example) may be used as the first metal layer 41, for example. A Cu film (with a thickness of 3.0 micrometers, for example) may be used as the second metal layer 42, for example.

Specifically, a Ti layer (with a thickness of 0.03 micrometers, for example) may be formed to cover the lower surface of the structure illustrated in FIG. 10 by use of a sputter method, for example. A plating-purpose resist film having openings at the positions where the interconnections 36 and 49 are to be formed may then be formed on the lower surface of the Ti layer. Electrolytic plating is then performed by using the Ti film as a power feeding layer to form a Cu layer (with a thickness of 3.0 micrometers, for example) on the lower surface of the Ti layer that is exposed through the openings of the plating-purpose resist film. After this, the plating-purpose resist film is removed. Then, the Ti layer is removed by etching at the positions where the Cu layer is not formed.

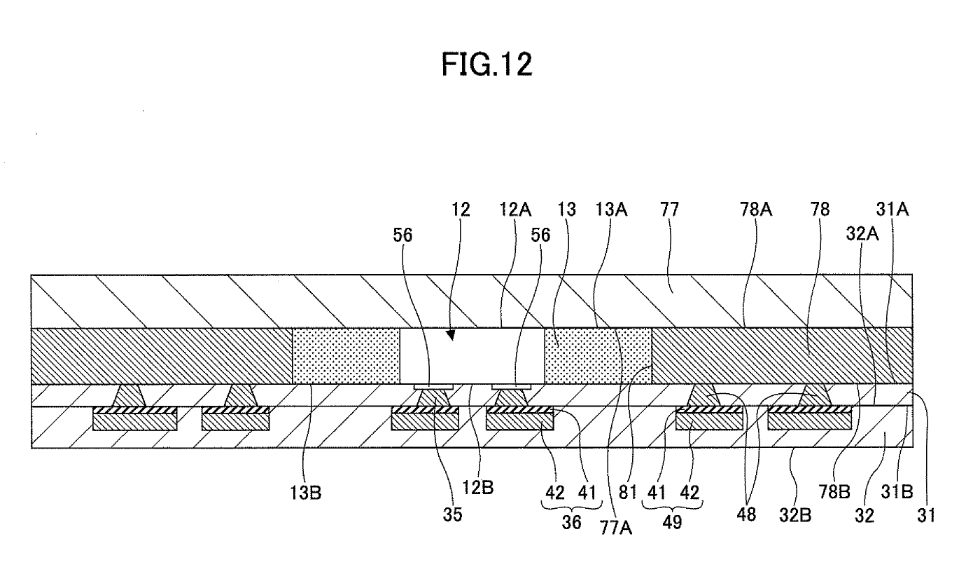

In the process step illustrated in FIG. 12, the insulating layer 32 that covers the interconnections 36 and 49 is formed on the lower surface 31B of the insulating layer 31. A photosensitive resin (e.g., epoxy resin), for example, may be used as the insulating layer 32. The thickness of the insulating layer 32 may be 5 to 6 micrometers, for example. The insulating layer 32 may be formed by employing a process step similar to the process step as previously described in connection with FIG. 8.

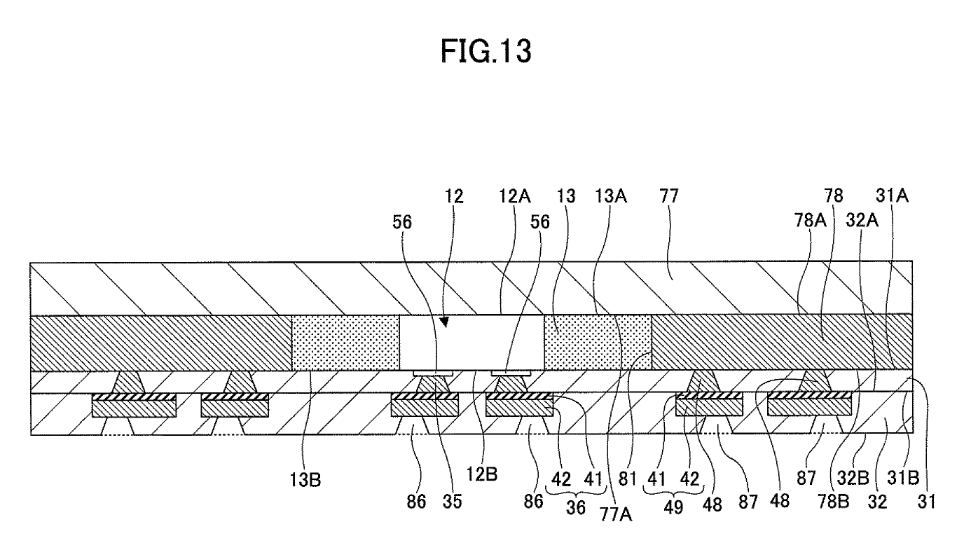

In the process step illustrated in FIG. 13, openings 86 to expose the second metal layer 42 of the interconnection 36 and openings 87 to expose the second metal layer 42 of the interconnection 49 are formed through the insulating layer 32 from below the lower surface 32B of the insulating layer 32. Specifically, a process similar to the process step described in connection with FIG. 9 is performed to form the openings 86 and 87.

The insulating layer 32 having the openings 86 and 87 may be formed by a method different from the one described above. In the case of the insulating layer 32 being a polyimide resin or epoxy resin that is not a photosensitive resin, for example, the insulating layer 32 having the openings 86 and 87 may be formed by using a laser process to shape the polyimide resin or epoxy resin at the positions where the openings 86 and 87 are to be formed.

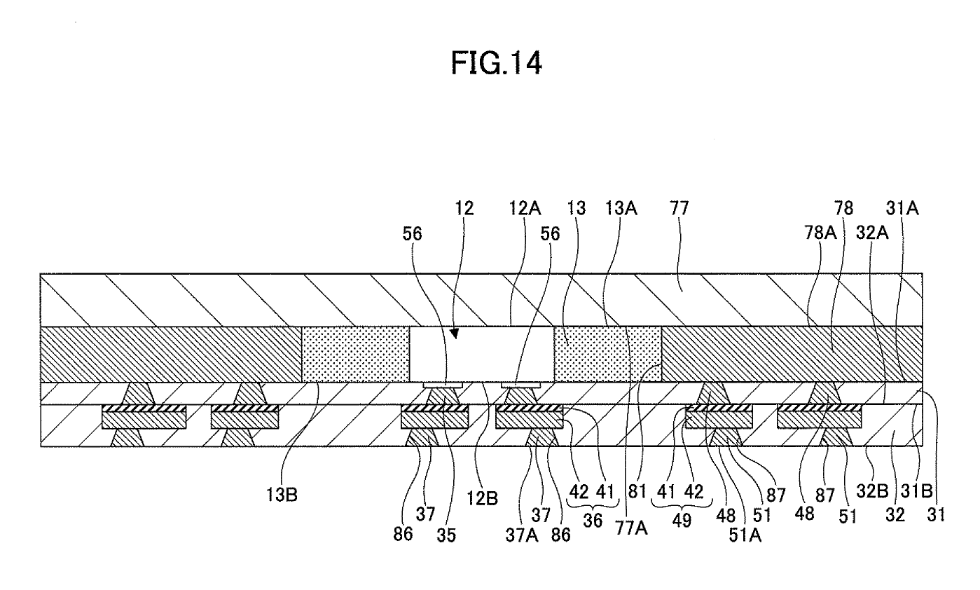

In the process step illustrated in FIG. 14, the vias 37 are formed to fill the openings 86 and are electrically connected to the interconnection 36, and the vias 51 are formed to fill the openings 87 and are electrically connected to the interconnection 49. In so doing, the vias 37 and 51 are formed such that the lower surfaces 37A and 51A of the vias 37 and 51 are substantially flush with the lower surface 32B of the insulating layer 32. Cu may be used as the material of the vias 37 and 51. The vias 37 and 51 may be formed by employing a process step similar to the process step as previously described in connection with FIG. 10.

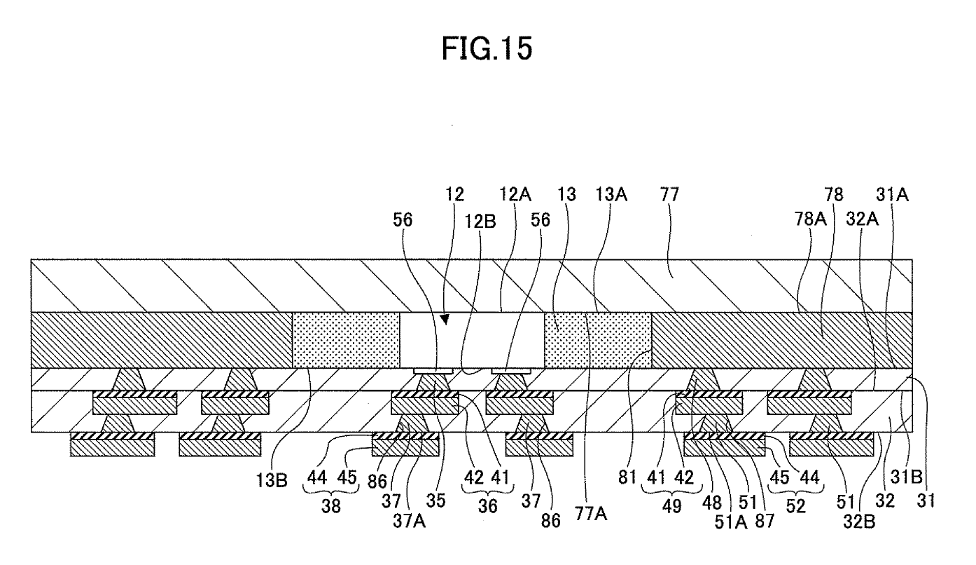

In the process step illustrated in FIG. 15, the interconnection 38 comprised of the first metal layer 44 and the second metal layer 45 is formed on the lower surface 37A of the via 37 and the lower surface 32B of the insulating layer 32. Further, the interconnection 52 comprised of the first metal layer 44 and the second metal layer 45 is formed on the lower surface 51A of the via 51 and the lower surface 32B of the insulating layer 32. The interconnections 38 and 52 are interconnection lines that are wider than the interconnections 36 and 49. The width of the interconnections 38 and 52 may be 10 micrometers, for example. A Ti film (with a thickness of 0.03 micrometers, for example) may be used as the first metal layer 44, for example. A Cu film (with a thickness of 3.0 micrometers, for example) may be used as the second metal layer 45, for example. The interconnections 38 and 52 may be formed by employing a process step similar to the process step as previously described in connection with FIG. 11.

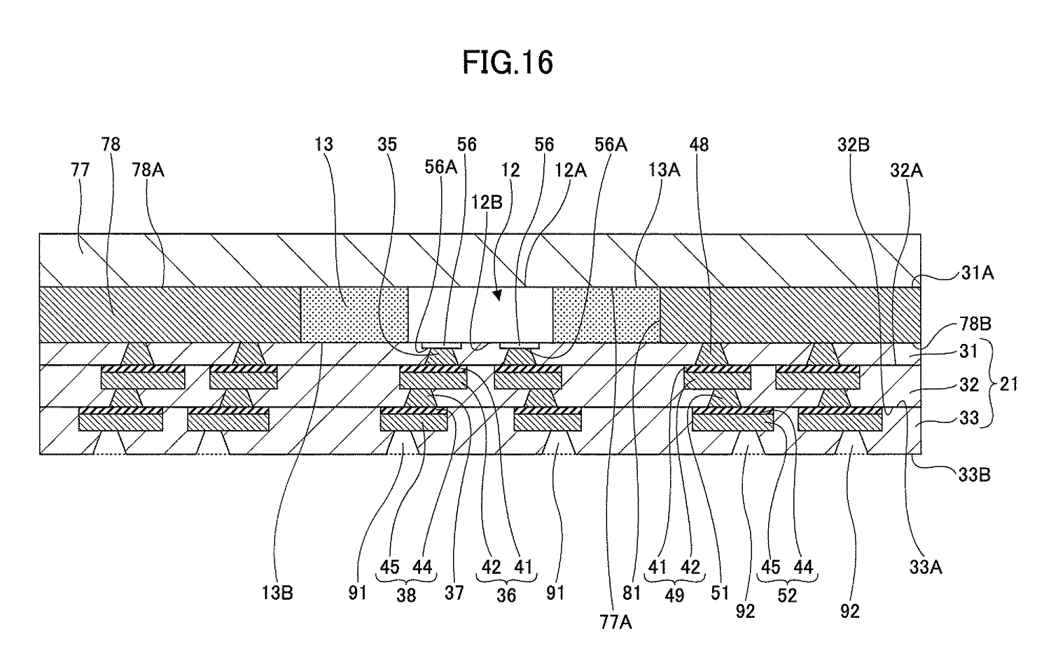

In the process step illustrated in FIG. 16, the insulating layer 33 is formed on the lower surface of the structure illustrated in FIG. 15 by performing a process similar to the process steps described in connection with FIG. 8 and FIG. 9, such that the insulating layer 33 has openings 91 to expose the second metal layer 45 of the interconnection 38 and openings 92 to expose the second metal layer 45 of the interconnection 52. In this manner, the multilayer structure 21 comprised of the insulating layers 31 through 33 stacked in a multilayer structure is formed. A photosensitive resin (e.g., epoxy resin), for example, may be used as the insulating layer 33. The thickness of the insulating layer 33 may be about 10 micrometers, for example.

The insulating layer 33 having the openings 91 and 92 may be formed by a method different from the one described above. In the case of the insulating layer 33 being a polyimide resin or epoxy resin that is not a photosensitive resin, for example, the insulating layer 31 having the openings 91 and 92 may be formed by using a laser process to shape the polyimide resin or epoxy resin at the positions where the openings 91 and 92 are to be formed.

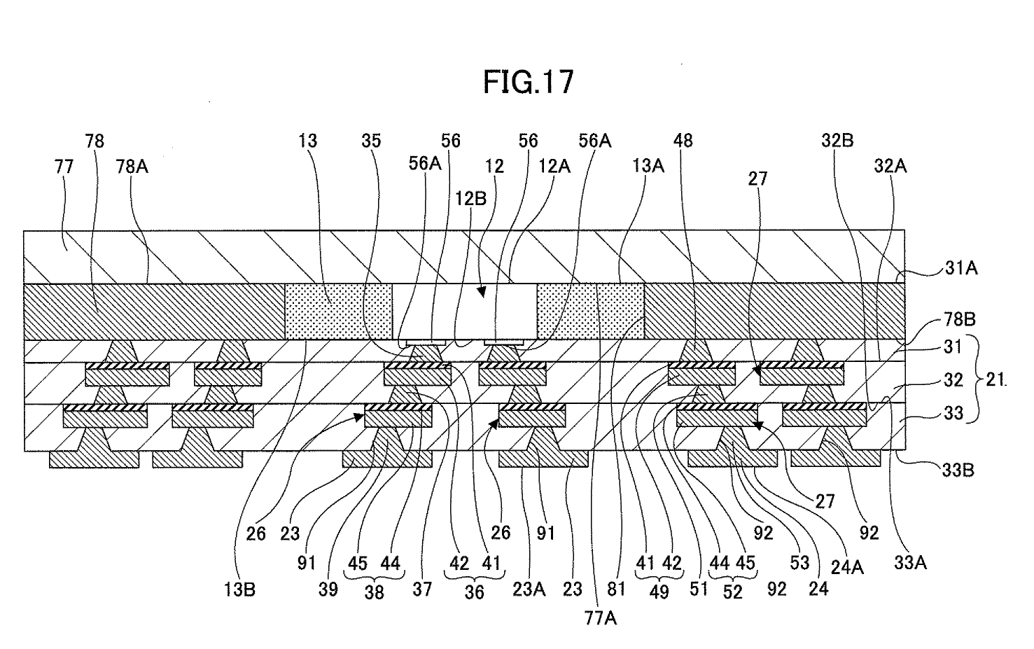

In the process step illustrated in FIG. 17, the vias 39, the first external connection pads 23, the vias 53, and the second external connection pads 24 are simultaneously formed. The vias 39 fill the openings 91 to be connected to the second metal layer 45 of the interconnection 38. Each of the first external connection pads 23 is formed integrally with a corresponding one of the vias 39 as a unitary structure, and is situated on the lower surface 33B of the insulating layer 33 The vias 53 fill the openings 92 to be connected to the second metal layer 45 of the interconnection 52. Each of the second external connection pads 24 is formed integrally with a corresponding one of the vias 53 as a unitary structure, and is situated on the lower surface 33B of the insulating layer 33 Specifically, the vias 39 and 53, the first external connection pads 23, and the second external connection pads 24 may be formed by a semi-additive method, for example.

In this manner, the first interconnection patterns 26, each of which includes the vias 35, 37, and 39 and the interconnections 36 and 38 and connects between one of the electrode pads 56 and one of the first external connection pads 23, are formed. Further, the second interconnection patterns 27, each of which includes the vias 48, 51, and 53 and the interconnections 49 and 52 and connects between the metal film 78 and one of the second external connection pads 24, are formed. The material of the vias 39 and 53, the first external connection pads 23, and the second external connection pads 24 may be Cu, for example.

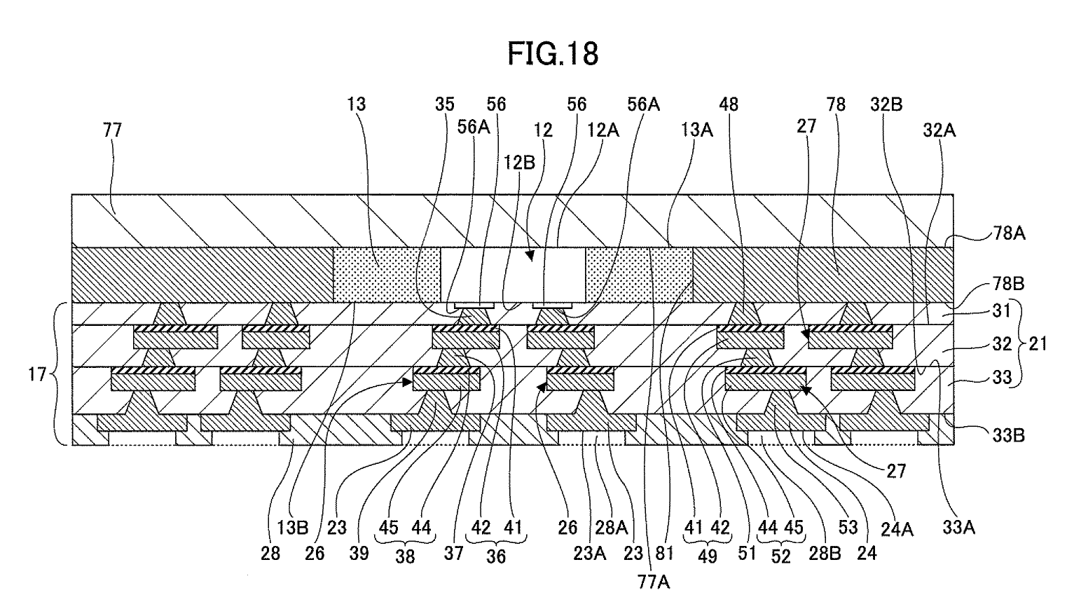

In the process step illustrated in FIG. 18, the solder resist layer 28 is formed on the lower surface 33B of the insulating layer 33 to have an opening 28A to expose the connection surface 23A of the first external connection pad 23 and an opening 28B to expose the connection surface 24A of the second external connection pad 24. In this manner, the multilayer interconnection structure 17 is formed that includes the multilayer structure 21, the first and second external connection pads 23 and 24, the first and second interconnection patterns 26 and 27, and the solder resist layer 28. The process steps illustrated in FIG. 8 through FIG. 18 are referred to as a multilayer interconnection structure forming step.

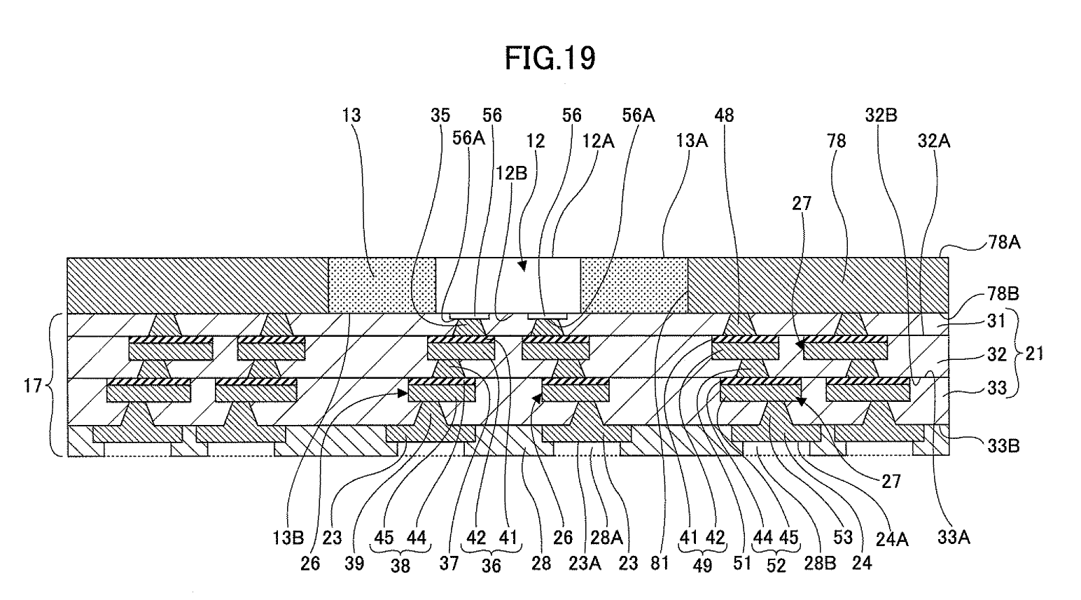

In the process step illustrated in FIG. 19, the support member 77 illustrated in FIG. 18 is removed. This process step is referred to as a support member removing step. Specifically, in the case of the support member 77 being a silicon substrate, the support member 77 is removed by mechanically detaching the support member 77 from the first electronic component 12, the sealing resin 13, and the metal film 78, for example.

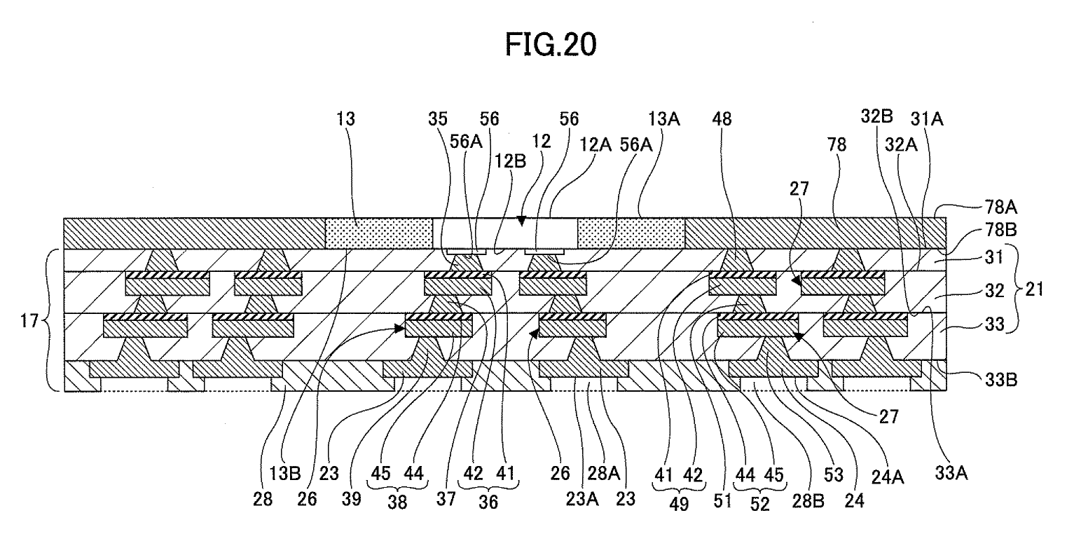

In the process step illustrated in FIG. 20, the first electronic component 12, the sealing resin 13, and the metal film 78 illustrated in FIG. 19 are ground from the upper surface side of the structure illustrated in FIG. 19, i.e., from the back surfaces 12A, 13A, and 78A of the first electronic component 12, the sealing resin 13, and the metal film 78. The first electronic component 12 is thus made into a thin plate shape (i.e., the thickness of the first electronic component 12 is reduced), and, also, the thickness of the sealing resin 13 and the metal film 78 is reduced. This process step is referred to as a grinding step. Specifically, a backside grinder may be used to grind the first electronic component 12, the sealing resin 13, and the metal film 78.

In the manner as described above, the first electronic component 12, the sealing resin 13, and the metal film 78 disposed on the multilayer interconnection structure 17 are ground, thereby reducing the thickness of the first electronic component 12, the sealing resin 13, and the metal film 78. Accordingly, the size of the semiconductor device 10 in the thickness direction can be reduced.

In the grinding step described above, grinding is performed such that the thicknesses of the first electronic component 12, the sealing resin 13, and the metal film 78 are substantially equal to each other after the grinding. In other words, the back surface 12A of the first electronic component 12, the upper surface 13A of the sealing resin 13, and the upper surface 78A of the metal film 78 are flush with each other after grinding is performed. In the grinding step, further, grinding is performed such that the back surface 12A of the first electronic component 12, the upper surface 13A of the sealing resin 13, and the upper surface 78A of the metal film 78 are flat after the grinding. The thickness of the first electronic component 12, the sealing resin 13, and the metal film 78 may be 300 micrometers, for example.

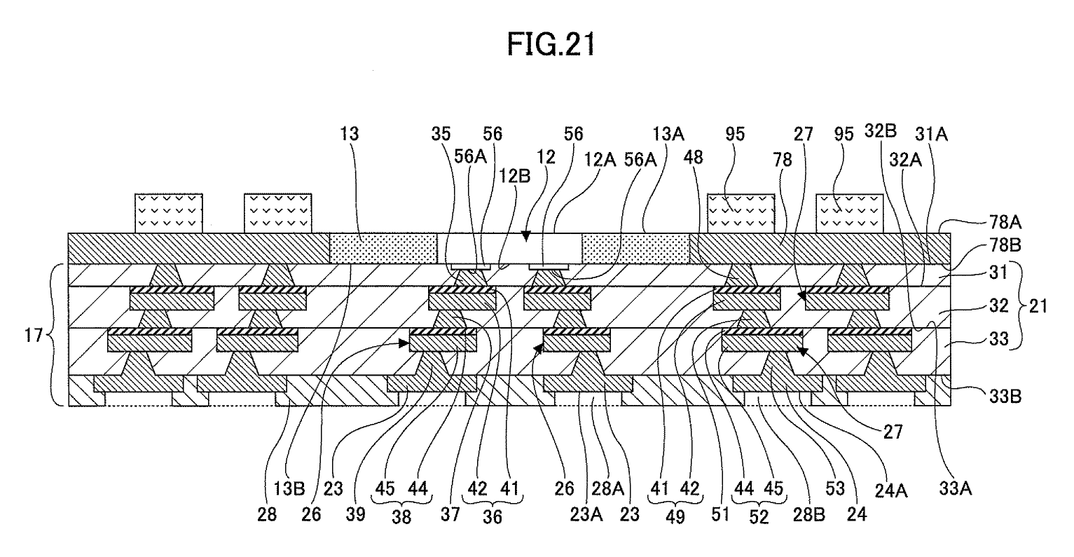

In the process step illustrated in FIG. 21, a resist film 95 is formed on the upper surface 78A of the metal film 78 to cover the upper surface 78A of the metal film 78 at the positions where the pads 22 are to be formed.

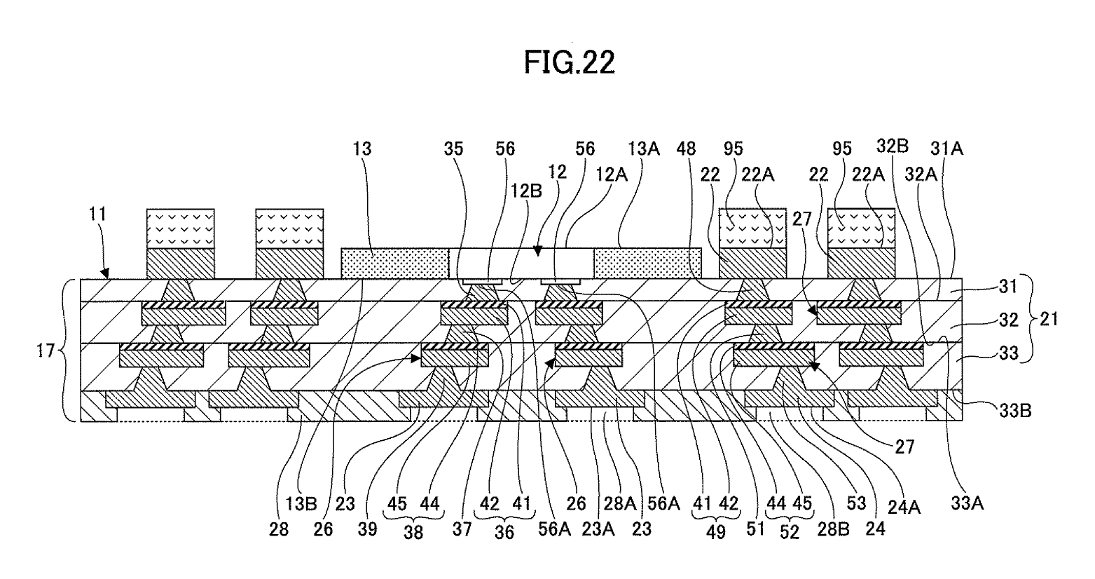

In the process step illustrated in FIG. 22, the metal film 78 that is not covered by the resist film 95 (see FIG. 21) is removed by etching (e.g., anisotropic etching) that uses the resist film 95 as a mask. This results in the pads 22 being formed that are connected to the second interconnection patterns 27.

The upper surfaces 22A of the pads 22 are configured to be substantially flush with the back surface 12A of the first electronic component 12 and the upper surface 13A of the sealing resin 13 that are processed by grinding. The shape of each pad 22 may be a pillar shape (e.g., cylindrical shape). When the shape of each pad 22 is cylindrical, the diameter of each pad 22 may be 100 to 300 micrometers, for example. The thickness of the pads 22 may be 200 to 300 micrometers, for example. Cu may be used as the material of the pads 22. The process steps illustrated in FIG. 21 and FIG. 22 are referred to together as a pad forming step.

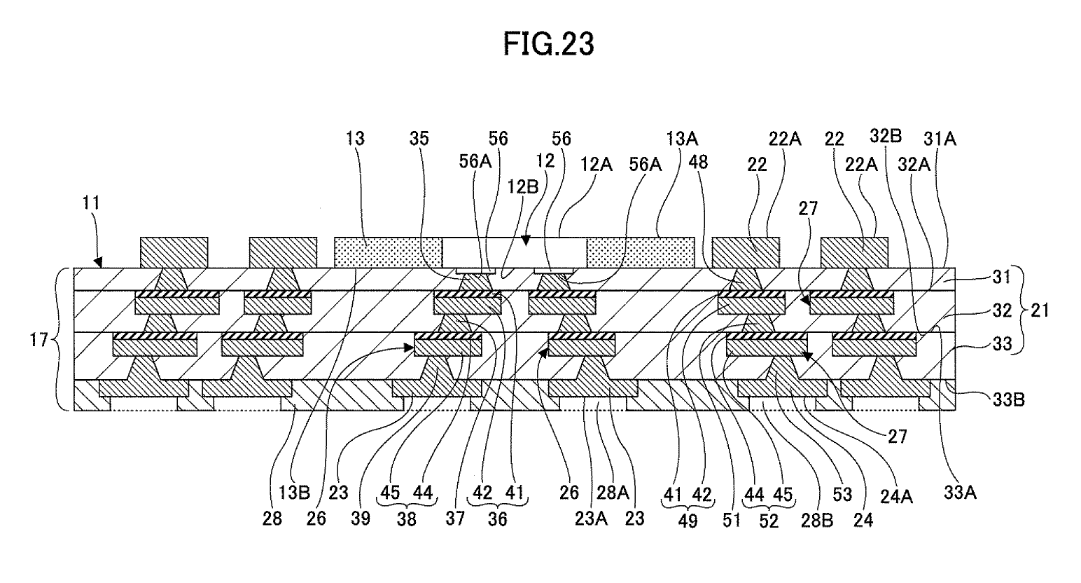

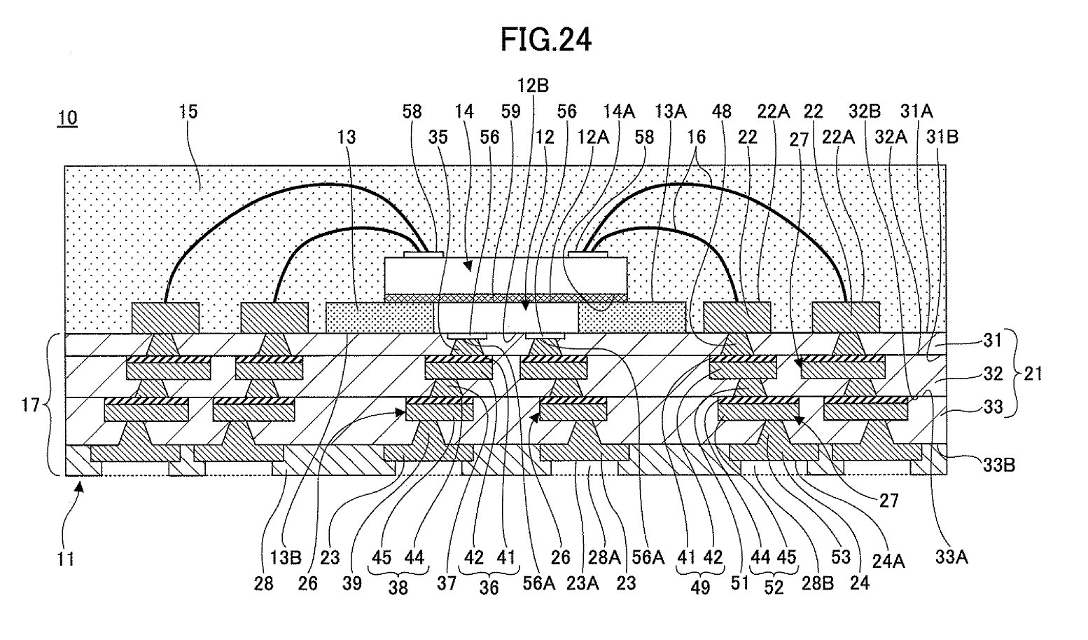

In the process step illustrated in FIG. 23, the resist film 95 illustrated in FIG. 22 is removed. Electroless plating may be performed to form a Ni plating layer and an Au plating layer successively on the surfaces of the pads 22 thereby to form a protective layer comprised of a Ni and Au multilayer film. In the process step illustrated in FIG. 24, the surface 14A of the second electronic component (i.e., the surface of the second electronic component 14 opposite the surface on which the electrode pads 58 are formed) is adhesively connected by the adhesive agent 59 to the back surface 12A of the first electronic component 12 and to the upper surface 13A of the sealing resin 13. Thereafter, the metal wires 16 (e.g., Au wires) are formed to connect between the electrode pads 58 formed on the second electronic component 14 and the pads 22. With this arrangement, the second electronic component 14 is connected by wire bonding to the wiring substrate 11. This process step is referred to as a second electronic component mounting step.

The second electronic component 14 has a larger surface size than the first electronic component 12. The second electronic component 14 may be a semiconductor chip that is a memory.

In this manner, the upper surface 13A of the sealing resin 13, the back surface 12A of the first electronic component 12, and the upper surfaces 22A of the pads 22 are flush with each other after the grinding step. Further, the second electronic component 14 is adhesively bonded to the back surface 12A of the first electronic component 12 and the upper surface 13A of the sealing resin 13. With this provision, the entirety of the surface 14A of the second electronic component 14 that faces the first electronic component 12 and the sealing resin 13 can be adhesively connected to the back surface 12A of the first electronic component 12 and the upper surface 13A of the sealing resin 13 even when the surface area size of the second electronic component 14 is larger than the surface area size of the first electronic component 12. Accordingly, the second electronic component 14 having a larger surface size than the first electronic component 12 can be fixedly mounted to the first electronic component 12 in a stable manner.

According to the method of manufacturing a semiconductor device of the present embodiment, the metal film 78 having substantially the same thickness as the first electronic component 12 is formed on the lower surface 77A of the support member 77 such that the metal film 78 has the hole exposing the lower surface 77A of the support member 77. Thereafter, the first electronic component 12 is adhesively connected to the lower surface 77A of the support member 77 that is exposed through the hole 81 such that the connection surfaces 56A of the electrode pads 56 and the lower surface 78B of the metal film 78 are substantially flush with each other. After this, the sealing resin 13 is formed to seal the first electronic component in the hole 81. The sealing resin 13 has the lower surface 13B that is substantially flush with the connection surfaces 56A of the electrode pads 56 and the lower surface 78B of the metal film 78. The multilayer interconnection structure 17 is then formed on the connection surfaces 56A of the electrode pads 56, the lower surface 78B of the metal film 78, and the lower surface 13B of the sealing resin 13. This is followed by the removal of the support member 77. Further, the first interconnection patterns 26 are formed and directly connected to the connection surfaces 56A of the electrode pads 56 in the multilayer interconnection structure forming step. This arrangement makes it possible to establish an electrical connection between the first electronic component 12 and the wiring substrate 11 without using a bump. Accordingly, the size of the semiconductor device 10 in the thickness direction can be reduced.

After the grinding step, the metal film 78 is patterned to form the pads 22. The second electronic component 14 is then adhesively bonded to the back surface 12A of the first electronic component 12 and the upper surface 13A of the sealing resin 13, and the electrode pads 58 of the second electronic component 14 are connected to the pads 22 through wire bonding. With this provision, the entirety of the surface 14A of the second electronic component 14 can be adhesively connected to the back surface 12A of the first electronic component 12 and to the upper surface 13A of the sealing resin 13 even when the surface size of the second electronic component 14 is larger than the surface size of the first electronic component 12. Namely, the second electronic component 14 is fixedly mounted on the first electronic component 12 in a stable manner.

In the process steps illustrated in FIG. 4 through FIG. 18 described above, the multilayer interconnection structure 17 is illustrated as being formed beneath the lower surface 77A of the support member 77 for the sake of convenience of explanation, i.e., for the purpose of avoiding the need to flip the semiconductor device 10 upside down during the manufacturing steps. In reality, however, the multilayer interconnection structure 17 is formed on the lower surface 77A of the support member 77 with the lower surface 77A of the support member 77 facing upward, i.e., with the structure illustrated in FIG. 4 through FIG. 18 being flipped upside down. When the semiconductor device 10 is manufactured with the structure illustrated in FIG. 4 through FIG. 18 placed upside down (i.e., when the semiconductor device 10 is manufactured in a real manufacturing process), the lower surface 77A of the support member 77 becomes an upper surface of the support member 77. Further, the lower surface 78B of the metal film 78 is actually an upper surface of the metal film 78. The lower surface 13B of the sealing resin 13 is actually an upper surface of the sealing resin 13.

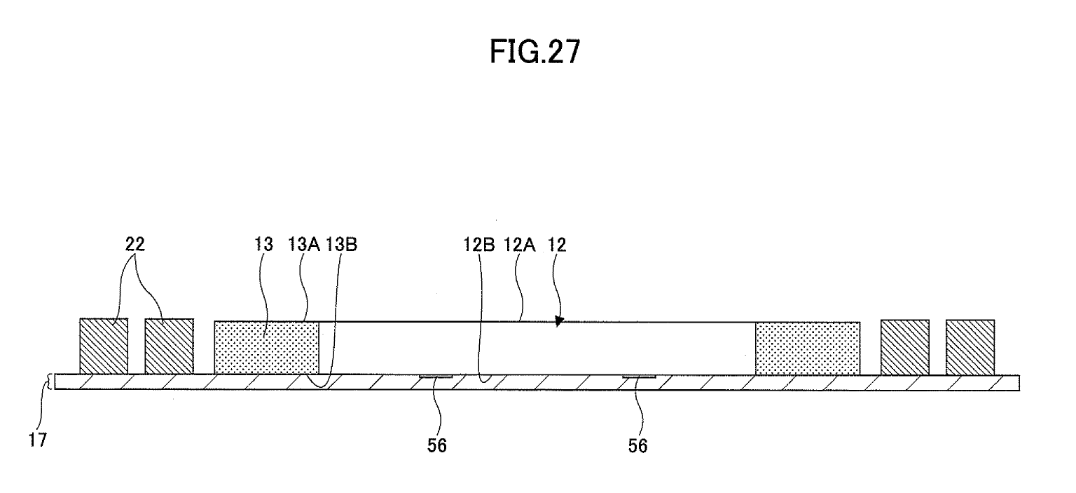

It should be noted that the structure (as illustrated in FIG. 23 and FIG. 27) obtained by removing the sealing resin 15, the second electronic component 14, the metal wires 16, and the adhesive agent 59 from the semiconductor device 10 of the first embodiment may also serve as a semiconductor device product.

Further, the structure obtained by removing the second electronic component 68, the underfill resin 71, and the internal connection terminals 69 from the semiconductor device 65 of the variation of the first embodiment may also serve as a semiconductor device product.

Moreover, when the semiconductor device 65 according to the variation of the first embodiment is to be manufactured, the solder resist layer 72 is formed on the upper surface 31A of the insulating layer 31 after the process step illustrated in FIG. 23. The second electronic component 68 is then mounted.

### Second Embodiment

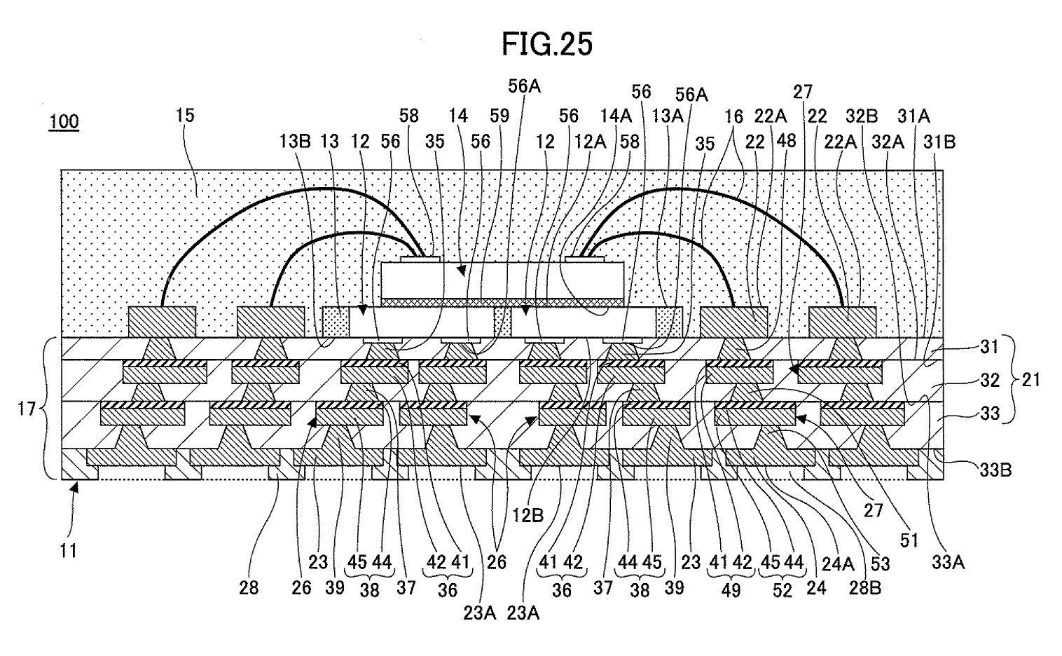

FIG. 25 is a cross-sectional view of a semiconductor device according to a second embodiment. In FIG. 25, the same elements as those of the semiconductor device 10 of the first embodiment are referred to by the same numerals.

A semiconductor device 100 of the second embodiment illustrated in FIG. 25 has the same configuration as the semiconductor device 10 of the first embodiment, except that a plurality of first electronic components 12 are provided.

The first electronic components 12 are situated on the upper surface 31A of the insulating layer 31. The electrode pads 56 of the first electronic components 12 are directly connected to the top ends of the vias 35.

The sealing resin 13 is disposed on the sides of the first electronic components 12 and between the first electronic components 12. The upper surface 13A of the sealing resin 13 is configured to be substantially flush with the back surfaces 12A of the first electronic components 12.

The second electronic component 14 is adhesively connected through the adhesive agent 59 to the back surfaces 12A of the first electronic components 12 and the upper surface 13A of the sealing resin 13.

The semiconductor device 100 of the second embodiment having the above-described configuration provides the same advantages as the semiconductor device 10 of the first embodiment.

The semiconductor device 100 of the second embodiment may be manufactured through substantially the same process steps as the process steps of manufacturing the semiconductor device 10 of the first embodiment. Such a manufacturing method provides the same advantages as the manufacturing method for manufacturing the semiconductor device 10 of the first embodiment.

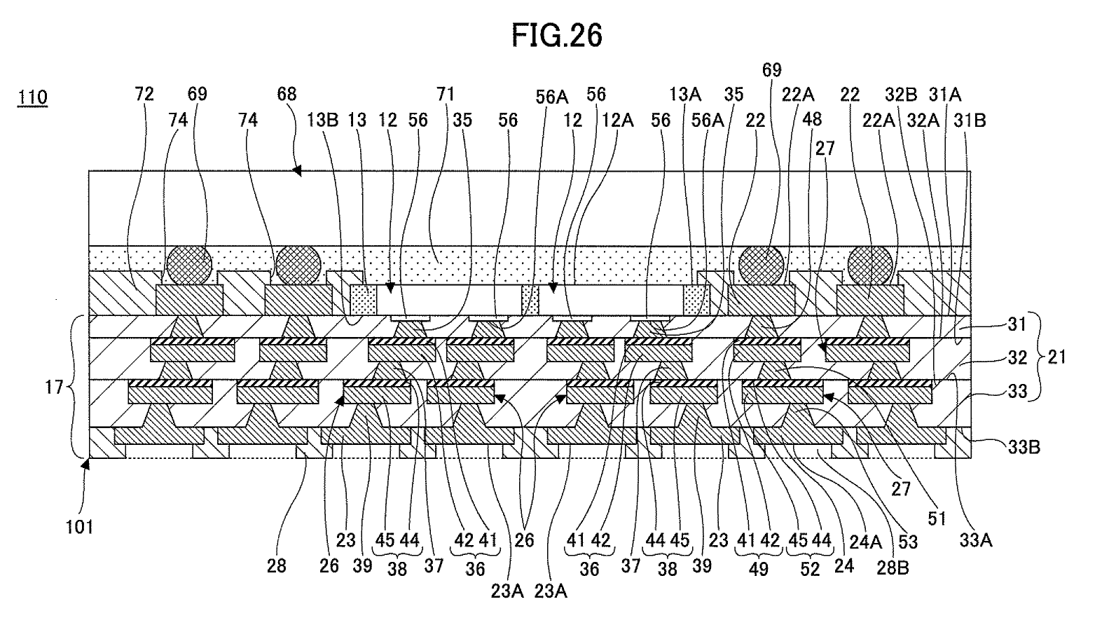

FIG. 26 is a cross-sectional view of a semiconductor device according to a variation of the second embodiment. In FIG. 26, the same elements as those of the semiconductor device 100 of the second embodiment are referred to by the same numerals.

A semiconductor device 110 illustrated in FIG. 26 according to the variation of the second embodiment includes a plurality of first electronic components 12, a sealing resin 13, a wiring substrate 101, a second electronic component 68, internal connection terminals 69, and an underfill resin 71.

The wiring substrate 101 is configured substantially in the same fashion as the wiring substrate 11, except that a solder resist layer 72 is provided in addition to the configuration of the wiring substrate 11 used in the semiconductor device 100 of the second embodiment.

The solder resist layer 72 is formed on the upper surface 31A of the insulating layer 31. The solder resist layer 72 has openings 74 that expose the upper surfaces 22A of the pads 22.

The second electronic component 68 is situated over the upper surface of the wiring substrate 101. The second electronic component 68 is electrically connected to the internal connection terminals 69. The second electronic component 68 is electrically connected (flip-chip connected) to the wiring substrate 101 through the internal connection terminals 69. The second electronic component 68 may be a semiconductor chip that is a memory.

The internal connection terminals 69 are disposed on the upper surfaces 22A of the pads 22 exposed through the openings 74, and are electrically connected to the second electronic component 68. Solder bumps may be used as the internal connection terminals 69.

The underfill resin 71 is disposed to fill the gap between the second electronic component 68 and the wiring substrate 101.

In the semiconductor device according to the variation of the second embodiment, any given one of the electrode pads 56 formed on the first electronic components 12 is directly connected to the portion of the first interconnection pattern 26 that is exposed from the upper surface 31A of the insulating layer 31. Further, the second electronic component 68 is flip-chip connected to the pads 22. With this arrangement, the size of the semiconductor device 110 in the thickness direction can be reduced, compared with the case in which the second electronic component 68 is connected through wire bonding to the pads 22.

In place of the second electronic component 68, another semiconductor device (not shown) or another wiring substrate (not shown) may be provided, and may be electrically connected to the pads 22 through the internal connection terminals 69. In this case, solder balls may be used as the internal connection terminals 69.

In the embodiments and variations described heretofore, the first interconnection patterns 26 and the second interconnection patterns 27 may be connected to each other in the multilayer interconnection structure 17.

Further, the present invention is not limited to these embodiments, but various variations and modifications may be made without departing from the scope of the present invention.

FIG. 27 is a drawing for illustrating actual thickness relationships between a first electronic component, a sealing resin, pads, and a multilayer interconnection structure.

In connection with FIG. 2 through FIG. 26, descriptions have been given by providing a detailed illustration of the configuration of the multilayer interconnection structure 17. As a result, thickness relationships between the first electronic component 12, the sealing resin 13, the pads 22, and the multilayer interconnection structure 17 illustrated in FIG. 2 through FIG. 26 are different from the actual thickness relationships between the first electronic component 12, the sealing resin 13, the pads 22, and the multilayer interconnection structure 17. In FIG. 2 through FIG. 26, the thickness of the multilayer interconnection structure 17 is thicker than the thickness of the first electronic component 12, the thickness of the sealing resin 13, and the thickness of the pads 22. In reality, however, the thickness of the multilayer interconnection structure 17 (e.g., 20 to 30 micrometers) is substantially thinner than the thickness of the first electronic component 12 (e.g., 200 to 300 micrometers), the thickness of the sealing resin 13 (e.g., 200 to 300 micrometers), and the thickness of the pads 22 (e.g., 200 to 300 micrometers). Further, the multilayer interconnection structure 17 is formed as a layer or film on the electrode pad forming surface 12B of the first electronic component 12, the lower surface 13B of the sealing resin 13, and the lower surfaces of the pads 22.

The present application is based on Japanese priority application No. 2009-037305 filed on Feb. 20, 2009, with the Japanese Patent Office, the entire contents of which are hereby incorporated by reference.

What is claimed is:

1. A semiconductor device, comprising:
a first electronic component having an electrode pad forming surface on which a first electrode pad is formed, and having a back surface opposite the electrode pad forming surface;
a sealing resin having a first surface and a second surface, the sealing resin being disposed to cover side faces of the first electronic component while exposing the electrode pad forming surface at the first surface and the back surface at the second surface;
a multilayer interconnection structure including insulating layers stacked one over another and interconnection patterns, the multilayer interconnection structure having an upper surface thereof being in contact with the first surface of the sealing resin, the first electrode pad, and the electrode pad forming surface, and the multilayer interconnection structure having a periphery thereof situated outside a periphery of the sealing resin; and
another pad disposed on the upper surface of the multilayer interconnection structure outside the periphery of the sealing resin,
wherein the interconnection patterns of the multilayer interconnection structure include a first interconnection pattern directly connected to the first electrode pad and a second interconnection pattern directly connected to said another pad.

2. The semiconductor device as claimed in claim 1, wherein the first interconnection pattern includes a portion that is directly connected to the first electrode pad, the portion being a via configured to penetrate through one of the insulating layers that forms the upper surface of the multilayer interconnection structure.

3. The semiconductor device as claimed in claim 1, wherein the second surface of the sealing resin is substantially flush with the back surface of the first electronic component.

4. The semiconductor device as claimed in claim 1, further comprising a second electronic component disposed on the back surface of the first electronic component and on the second surface of the sealing resin, the second electronic component having a second electrode pad that is electrically connected to said another pad.

5. A method of manufacturing a semiconductor device, comprising:
a metal film forming step of forming, on a first surface of a support member, a metal film having a hole that exposes the first surface of the support member;
a first electronic component mounting step of mounting the first electronic component having an electrode pad forming surface on which a first electrode pad is formed, and having a back surface opposite the electrode pad forming surface, by adhesively bonding the back surface of the first electronic component to the first surface of the support member that is exposed through the hole;
a sealing resin providing step of providing a sealing resin that seals the first electronic component in the hole;
a multilayer interconnection structure forming step of forming a multilayer interconnection structure including interconnection patterns and insulating layers stacked one over another on the first electrode pad, on the electrode pad forming surface, on the metal film, and on the sealing resin, the multilayer interconnection structure having a periphery thereof situated outside a periphery of the sealing resin;
a support member removal step of removing the support member after the multilayer interconnection structure forming step; and
a pad forming step of forming another pad by patterning the metal film after the support member removal step,
wherein the multilayer interconnection structure forming step forms the first interconnection pattern that is directly connected to the first electrode pad, and forms the second interconnection pattern that is connected to said another pad.

6. The method as claimed in claim 5, further comprising a grinding step of grinding the first electronic component, the metal film, and the sealing resin from a direction where the support member is removed to reduce a thickness of the first electronic component, the metal film, and the sealing resin, the grinding step being performed between the support member removal step and the pad forming step.

7. The method as claimed in claim 5, further comprising an external connection pad forming step of forming external connection pads on a surface of the multilayer interconnection structure that is opposite a surface in contact with the first electrode pad, the electrode pad forming surface, the metal film, and the sealing resin, the external connection pads being connected to the first interconnection pattern and to the second interconnection pattern.

8. The method as claimed in claim 5, further comprising a second electronic component mounting step of mounting a second electronic component on the back surface of the first electronic component and on the sealing resin, and electrically connecting a second electrode pad of the second electronic component to said another pad.
